(19) United States
(12) Patent Application Publication
(10) Pub. No.: US 2026/0170865 A1
(43) Pub. Date: Jun. 18, 2026

(54) FLEXIBLE BIOMETRIC SENSOR FOR HAND SCANNING

(71) Applicant: HID Global Corp., Austin, TX (US)

(72) Inventors: Daniel Henri Raguin, Jupiter, FL (US); George William McClurg, Jensen Beach, FL (US)

(21) Appl. No.: 18/981,797

(22) Filed: Dec. 16, 2024

(51) Int. Cl. G06V 40/13; H10D 86/01; H10D 86/40; H10F 39/00; H10F 39/12

(52) U.S. Cl. CPC G06V 40/1318; H10D 86/0221; H10D 86/411; H10F 39/016; H10F 39/12; H10F 39/8037

(57) ABSTRACT

A biometric scanning apparatus that includes a flexible pixelated sensor array configured to directly detect skin topology features. The sensor array is shaped into non-planar configurations with multiple surface portions oriented at different angles to ergonomically conform to natural hand anatomy. The flexible array, fabricated using thin-film transistor technology on ultrathin substrates, simultaneously captures fingerprints, palm prints, and thumb prints during a single hand placement. The pixelated array detects ridge/valley differences through optical, electrical, or ultrasonic sensing to generate standardized biometric templates.

### BACKGROUND

Fingerprint scanners have become commonly used to allow users to access secure resources and also to generate and/or access records for individuals. Some fingerprint scanners use prisms and free-space optics. Other types of fingerprint scanners include capacitive sensing and optical sensing touch-type scanners. Usually, touch-type sensors have a sensing area that is generally the same as the area of the finger being scanned. For the case of silicon backplane touch-type sensors, these sensors are rarely larger than a half inch along any dimension due to the drop in yield for larger silicon dies.

### BRIEF SUMMARY

In some aspects, the techniques described herein relate to a system including: one or more hardware processors; and at least one machine-storage medium for storing instructions that, when executed by the one or more hardware processors, cause the one or more hardware processors to perform operations including: communicating with a flexible pixelated sensor array configured to directly detect skin topology features, the flexible pixelated sensor array includes pixels arranged to detect signal differences between skin ridge contact locations and skin valley locations, the flexible pixelated sensor array being shaped into a non-planar configuration having one or more surface portions oriented at different angles relative to each other; and causing the flexible pixelated sensor array to capture biometric features from multiple portions of a user's hand during a single hand placement. The single hand placement including one hand or two hands and refers to capturing of an image without repositioning the one hand or two hands.

In some aspects, the techniques described herein relate to a system, wherein the captured biometric features include at least one of fingerprints from multiple fingers or a palm print.

In some aspects, the techniques described herein relate to a system, wherein the captured biometric features further include a thumbprint.

In some aspects, the techniques described herein relate to a system, the operations further including: causing the flexible pixelated sensor array to capture palm prints and fingerprints during the single hand placement.

In some aspects, the techniques described herein relate to a system, the operations further including: causing the flexible pixelated sensor array to capture a thumbprint on a surface portion while capturing fingerprints on an angled surface portion during the single hand placement.

In some aspects, the techniques described herein relate to a system, wherein the non-planar configuration includes a conical shape having a top surface for thumb placement.

In some aspects, the techniques described herein relate to a system, wherein the operations further include: causing the flexible pixelated sensor array to capture rolled fingerprints on the top surface by enabling a user to roll individual fingers across the top surface while maintaining the conical shape for palm and finger placement.

In some aspects, the techniques described herein relate to a system, wherein the conical shape includes an additional surface for an additional thumb placement, the operations including: causing the flexible pixelated sensor array to capture a first thumbprint of a first thumb placed on the top surface, a second thumbprint of a second thumb placed on the additional surface, and a plurality of fingerprints on an angled surface portion during the single hand placement.

In some aspects, the techniques described herein relate to a system, wherein the conical shape includes two separate sensitive areas configured to capture biometric features respectively from two hands during the single hand placement, the two separate sensitive areas being separated by a gap to accommodate ergonomic hand placement.

In some aspects, the techniques described herein relate to a system, the separation between the sensitive areas corresponding to approximately a shoulder width.

In some aspects, the techniques described herein relate to a system, wherein the non-planar configuration includes a cylindrical shape having one or more angled side surfaces for thumb placement.

In some aspects, the techniques described herein relate to a system, wherein the non-planar configuration includes a pyramidal structure having at least three angled surfaces configured to capture thumb prints from either a left hand or a right hand using respective surfaces of the at least three angled surfaces.

In some aspects, the techniques described herein relate to a system, wherein the operations further include: causing the flexible pixelated sensor array to capture fingerprints from two or more fingers on a first surface of the three angled surfaces while capturing a thumb print on one of the remaining two angled surfaces during the single hand placement.

In some aspects, the techniques described herein relate to a system, wherein the flexible pixelated sensor array includes a thin-film transistor (TFT) array fabricated on an ultrathin glass or plastic substrate.

In some aspects, the techniques described herein relate to a system, wherein the pixels are configured to detect at least one of optical signals, electrical signals, capacitive signals, impedance signals, or ultrasonic signals.

In some aspects, the techniques described herein relate to a system, wherein the non-planar configuration includes: a curved surface portion configured to conform to a palm of the user's hand; a flat surface portion connected to the curved surface portion and configured to capture fingerprints from multiple fingers; and wherein the flat surface portion is further configured to enable capture of rolled fingerprints by allowing individual fingers to be rolled across edges of the flat surface portion.

In some aspects, the techniques described herein relate to a system, wherein the sensors are supported by a flexible mechanical support that is at least partially compliant to aid in ergonomical matching of the sensor surface to a geometry of the skin topology being presented.

In some aspects, the techniques described herein relate to a method including: communicating with a flexible pixelated sensor array configured to directly detect skin topology features, the flexible pixelated sensor array including pixels arranged to detect signal differences between skin ridge contact locations and skin valley locations, the flexible pixelated sensor array being shaped into a non-planar configuration having one or more surface portions oriented at different angles relative to each other; and causing the flexible pixelated sensor array to capture biometric features from multiple portions of a user's hand during a single hand placement.

In some aspects, the techniques described herein relate to a method of manufacturing a flexible pixelated sensor array, including: fabricating a thin-film transistor (TFT) array on a flexible substrate, the TFT array including pixels configured to detect signal differences between skin ridge contact locations and skin valley locations; patterning the pixels of the TFT array in a regular grid on the flexible substrate during manufacturing; separating the flexible substrate with the patterned TFT array from a temporary support backplane; and shaping the flexible substrate with the patterned TFT array into a non-planar configuration having one or more surface portions oriented at different angles relative to each other, the shaped configuration being supported by a mechanical structure to maintain the non-planar shape while allowing partial compliance to pressure from hand contact.

In some aspects, the techniques described herein relate to a method, wherein shaping the flexible substrate includes at least one of forming a conical configuration having a flat top surface, forming a cylindrical configuration having angled side surfaces, forming a configuration having a curved portion for palm contact and a flat portion for finger contact, or forming a pyramidal configuration having at least three angled surfaces.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a block diagram of an example typical touch-type fingerprint scanning system.

FIG. 2 illustrates different configurations of a flexible pixelated sensor array, according to some examples.

FIG. 3 illustrates another configuration of a flexible pixelated sensor array, according to some examples.

FIG. 4 illustrates a sensor array fabrication diagram, according to some examples.

FIG. 5 illustrates a sensor array fabrication diagram, according to some examples.

FIG. 6 illustrates a sensor array fabrication diagram and another configuration of the flexible pixelated sensor array, according to some examples.

FIG. 7 illustrates a sensor array fabrication diagram and another configuration of the flexible pixelated sensor array, according to some examples.

FIG. 8 illustrates another configuration of the flexible pixelated sensor array, according to some examples.

FIG. 9 illustrates another view of the configuration of the flexible pixelated sensor array of FIG. 8, according to some examples.

FIG. 10 illustrates a sensor array fabrication diagram for the configuration of FIG. 8, according to some examples.

FIG. 11 illustrates a routine for operating a flexible pixelated sensor array, according to some examples.

FIG. 12 illustrates a routine for fabricating a flexible pixelated sensor array, according to some examples.

FIG. 13 is a block diagram illustrating a representative software architecture, which may be used in conjunction with various hardware architectures herein described, according to some examples.

FIG. 14 is a diagrammatic representation of a machine in the form of a computer system within which a set of instructions may be executed for causing the machine to perform any one or more of the methodologies discussed herein, according to some examples.

### DETAILED DESCRIPTION

Example methods and systems for fingerprint/handprint scanning are described. In the following description, for purposes of explanation, numerous specific details are set forth in order to provide a thorough understanding of example embodiments. It will be evident, however, to one of ordinary skill in the art that embodiments of the disclosure may be practiced without these specific details. While the disclosed examples are discussed in relation to scanning a fingerprint and/or handprint, similar techniques can be applied to scan any other portion or region of a skin.

Typical fingerprint biometric devices predominantly use flat platens for capturing fingerprints and palm prints. This fundamental design limitation creates inherent inefficiencies when attempting to capture biometric data from naturally curved anatomical features like palms and fingers. For palm scanning specifically, the conventional approach requires an operator (such as law enforcement personnel) to apply external pressure to the back of a subject's hand to force the naturally cupped palm profile against a flat platen. This manual pressure technique, primarily used during criminal booking and background checks, is inefficient and potentially inconsistent.

Some systems address these limitations using complex mechanical solutions. For example, some systems employ motorized rotary mechanisms with optical line scanners, mirrors, lenses and sensors that need to be continuously repositioned to capture the full hand. These bulky systems require either hand motion or optomechanical system motion to function. For example, one approach involves using a heavy solid acrylic cone with an internal rotating illumination system while other approaches involve using a rolling cylindrical platen that requires users to draw their hand across the surface. These approaches rely on software to stitch individual line scans into composite images, which is an inherently slow process that produces inconsistent results.

The limitations of existing systems are particularly evident when attempting to capture thumb prints simultaneously with other fingerprints. Due to the natural anatomy of the human hand, when fingers are placed flat on a surface, the thumb is naturally rotated approximately 45 degrees. This anatomical reality usually requires separate scanning steps or can produce rotated, distorted thumb images that needs additional processing.

The disclosed techniques address these technical challenges through a flexible pixelated sensor array that directly detects skin topology features without requiring complex optical systems or moving parts. By utilizing TFT technology fabricated on, for example, ultrathin glass or plastic substrates, the sensor can be shaped into ergonomic non-planar configurations that naturally conform to the curved anatomical features of the human hand. The flexible sensor can be configured into various shapes like cones, cylinders, or combinations of curved and flat surfaces to simultaneously capture palm prints, fingerprints, and thumb prints during a single hand placement without rotation distortion. As used herein, “simultaneous” or “simultaneously” (when referring to fingerprint/handprint capture) refers to capturing multiple biometric features from a user's hand during a single hand placement without requiring the user to reposition their hand, even though the actual sensing and image capture of different portions may occur sequentially. For example, while a user maintains a single hand position, the system may first capture an image of the fingers, then capture an image of the thumb, and then return to capture another image of the fingers, with this sequence continuing until sufficient quality images are acquired for all desired portions. From the user's perspective, all portions are captured “simultaneously” since only a single hand placement is required, regardless of the sequential nature of the underlying image acquisition process.

The disclosed approach can eliminate the need for external pressure application, mechanical scanning systems, or image stitching while enabling a scanner that is lightweight, has no moving parts, and can be manufactured cost-effectively. The sensor's pixels can directly detect ridge and valley differences through optical, electrical or ultrasonic sensing, with the flexibility to incorporate compliant mechanical supports that allow the sensing surface to better match the curvature of the presented skin topology.

The disclosed techniques provide a scanning apparatus and method capable of capturing the surface topology of a subject's fingers or hand(s) through use of a non-planar platen. In some cases, the platen serves as the sensor surface for the skin's surface topology and no further imaging system is required. The image processing provides a means by which the raw image is corrected to comply with fingerprint biometric standards, such as those specified by the FBI, BSI, and STQC.

In some examples, a flexible two-dimensional (2D) pixelated sensor is provided, such as using TFT technology. The TFT photolithographic processing may be conducted on a flat but flexible backplane of such various materials, such as glass or plastic. For glass, ultrathin glass (e.g., sheets of glass) may be used that is 100 μm thick with a minimum bend radius of 90 mm or 30 μm glass sheets with minimum bend radius of a few mm. For plastic, polyethylene naphthalate (PEN) or polyethylene terephthalate (PET) sheets can be used. The thin flexible backplane of the TFT pixels can be temporarily supported during the fabrication process by a thicker backplane and then separated from this thicker backplane via heat and/or solvents after the TFT processing steps have concluded. The TFT sensor may have pixels that are optically sensitive, electrically sensitive (e.g., capacitive, impedance, etc.), or ultrasonically sensitive such that the pixels can detect a signal difference between spatial locations where a skin ridge touches the platen versus a skin valley is above the platen for the presented skin three-dimensional (3D) topology.

For integrating into a product, the flexible 2D sensor may be supported by a rigid support or may be supported by a flexible mechanical support to allow a certain amount of flexibility to allow the pressure of the biometric presentation to help shape the sensor surface such that it better matches the curvature of the skin topology presented. Further, the 2D sensor may have a profile, such as that of a convex cylinder or as a cone or any other profile that a 2D plane may conform with limited mechanical stresses.

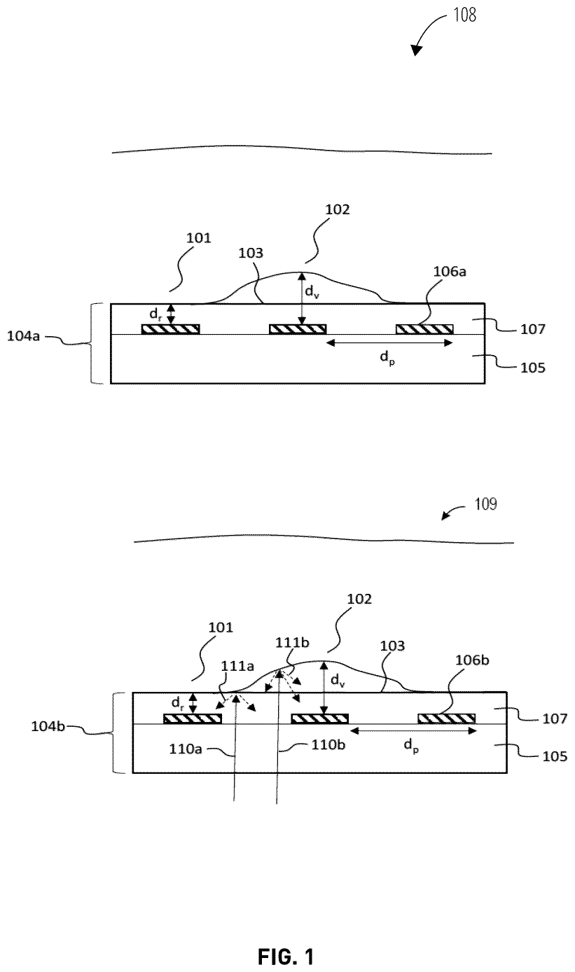

FIG. 1 is a block diagram of example typical fingerprint scanning systems 108 and 109. The fingerprint scanning systems can be implemented on or as part of a client device and be used in any of the below flexible pixelated sensor array configurations.

The client device can include any one or a combination of an IoT device, a database, a website, a server hosting a website at a URL address, a physical access control device, logical access control device, governmental entity device, ticketing event device, and residential smart lock and/or other Bluetooth or NFC or UWB based smart device. The client device may be, but is not limited to, an NFC powered microcontroller device like a smart card or USB dongle, a mobile phone, desktop computer, laptop, portable digital assistant (PDA), smart phone, a wearable device (e.g., a smart watch), tablet, ultrabook, netbook, multi-processor system, microprocessor-based or programmable consumer electronics, or any other communication device that a user may use to access a secure resource.

The client device can protect a secure area, asset, or resource and can be configured to receive a digital credential or digital credentials from the fingerprint scanning system 108/109. The client device can verify that the received digital credential or digital credentials is/are authorized to access the secure area, such as by communicating with an authentication server. In response, the client device can grant access to the secure area or protected resource. The client device itself or by communication with the authentication server can verify whether the digital credential or digital credentials is/are authorized to access the identified secure resource. If so, the client device can grant access (e.g., by unlocking an electronic door lock) for an individual associated with the client device.

A memory of the client device can include a computer-readable medium that can be any medium that can contain, store, communicate, or transport data, program code, or instructions for use by or in connection with client device. The computer-readable medium can be, for example but is not limited to, an electronic, magnetic, optical, electromagnetic, infrared, or semiconductor system, apparatus, or device. More specific examples of suitable computer-readable medium include, but are not limited to, an electrical connection having one or more wires or a tangible storage medium such as a portable computer diskette, a hard disk, a random access memory (RAM), a read-only memory (ROM), an erasable programmable read-only memory (EPROM or Flash memory), Dynamic RAM (DRAM), any solid-state storage device, in general, a compact disc read-only memory (CD-ROM), or other optical or magnetic storage device.

A processor of the client device can correspond to one or more computer processing devices or resources. For instance, the processor can be provided as silicon, as a Field Programmable Gate Array (FPGA), an Application-Specific Integrated Circuit (ASIC), any other type of Integrated Circuit (IC) chip, a collection of IC chips, or the like. As a more specific example, the processor can be provided as a microprocessor, Central Processing Unit (CPU), or plurality of microprocessors or CPUs that are configured to execute instruction sets stored in an internal memory and/or memory (carrier signals) of the client device.

A communication component of the client device can be configured to communicate according to any suitable communications protocol with one or more different systems or devices either remote or local to the client device, such as one or more other client devices over a communications network. In some cases, the communication module communicates over a secure channel (e.g., secure Bluetooth-Low Energy (BLE) or near-field communications (NFC) channel), in which case all of the exchanged data is encrypted (e.g., end-to-end). In some cases, the communication module communicates over an unsecure channel (e.g., unsecure, public or open BLE or NFC channel), in which case all or a portion of the exchanged data is unencrypted.

A network interface device of the client device includes hardware to facilitate communications with other devices over a communications network, utilizing any one of a number of transfer protocols (e.g., frame relay, internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), Plain Old Telephone (POTS) networks, wireless data networks (e.g., IEEE 802.11 family of standards known as Wi-Fi, IEEE 802.16 family of standards known as WiMax), IEEE 802.15.4 family of standards, and peer-to-peer (P2P) networks, among others. In some examples, network interface device can include an Ethernet port or other physical jack, a Wi-Fi card, a Network Interface Card (NIC), a cellular interface (e.g., antenna, filters, and associated circuitry), or the like. In some examples, network interface device can include a plurality of antennas to wirelessly communicate using at least one of single-input multiple-output (SIMO), multiple-input multiple-output (MIMO), or multiple-input single-output (MISO) techniques.

A user interface of the client device can include one or more input devices and/or display devices. Examples of suitable user input devices that can be included in the user interface include, without limitation, one or more buttons, a keyboard, a mouse, a touch-sensitive surface, a stylus, a camera, a microphone, and so forth. Examples of suitable user output devices that can be included in the user interface include, without limitation, one or more LEDs, an LCD panel, a display screen, a touchscreen, one or more lights, a speaker, and so forth. It should be appreciated that the user interface can also include a combined user input and user output device, such as a touch-sensitive display or the like.

The fingerprint scanning system 108 represents capacitive sensing pixels. Note that for simplicity, other components, such as one or more processors, transistors, power and communication lines to sensor pixels 106a have not been drawn in the fingerprint scanning system 108 but can be included as part of the fingerprint scanning system 108. In such a fingerprint scanning system 108, the fingerprint (and/or handprint) topology is generated based on electrical signals generated and captured responsive to skin touching platen 103 that covers one or more capacitive sensor pixels 106a. For example, the skin of, for example, a user's fingertip or other hand portion, is placed onto platen 103 of a scanner 104a. The skin may be that of a finger, fingers, hand, palm or other parts of skin where the 3D topology of the skin is to be mapped. In some cases, no physical height is being assigned to the 2D fingerprint data, as it may not be needed for matching. The signal differences can be grayscale differences and most of the valley can be one gray level and set to the same as the background image outside of the fingerprint.

The skin can have ridges 101 and valleys 102 that are mapped into a 3D topology or image by the sensor pixels 106a. Once mapped, the 3D topology or image is compared against one or more predetermined or known 3D topologies or images and/or stored as part of a profile or record for a person. In response to determining that the 3D topology or image generated based on the detected ridges 101 and valleys 102 corresponds to the one or more predetermined or known 3D topologies or images (e.g., a difference between the two topologies is less than a threshold), a match is determined and access to a secure resource can be granted and/or identity can be verified. The generation and comparison of the 3D topologies can be performed by one or more processors (not shown) coupled to or embedded in the fingerprint scanning system 108.

The scanner 104a can include a series of sensitive sensor pixels 106a arranged in an array on a backplane 105 and with a protective cover 107 (such as an SiO2 film, planarizing polymer layer, or a thin glass cover). The protective cover 107 is generally needed to protect the underlying sensor electronics from environmental conditions such as mechanical abrasion, electrostatic discharge (ESD), and a variety of cleaning chemicals, not to mention ambient humidity. Backplane 105 is typically silicon for silicon wafer-processed sensors and glass for sensors fabricated based upon TFT technology. Other materials for the backplane 105 can be provided, such as plastic, ultrathin glass, and so forth. From a scale standpoint, the sensor pixels 106a can be approximately a micron more or less in height, the protective cover 107 can be few microns to ten or thirty microns and the pixel-pixel spacing (dₚ) can be 50.8 um for the case of a 500 points-per-inch (ppi) sensor. Any other suitable pixel-pixel spacing can be provided and can depend on the ppi of the sensor. Valleys 102 of the skin topology such as with a fingerprint can be recessed 50-100 um below the level of the ridge 101.

For the fingerprint scanning system 108 in which capacitive scanning is performed, the sensor pixels 106a serve as one end of a capacitor and the skin serves as the other end of the capacitor. Specifically, the one or more processors of the fingerprint scanning system 108 can communicate with the sensor pixels 106a to receive electrical signals captured by the sensor pixels 106a. The electrical signals represent a capacitance value between each one of the sensor pixels 106a and a corresponding portion of the skin (e.g., ridge 101 or valley 102). The one or more processors compute a capacitance based on the measured electrical signals and generate a 3D topology representing the portion of the skin based on the different capacitance values obtained from each of the one or more sensor pixels 106a. In an example, capacitance varies inversely with the distance between two plates of the capacitor. In this way, the one or more processors can compute a measured capacitance of the ridge 101 as a greater value than the measured capacitance for the valley 102 since dᵣ is smaller than dᵥ by a factor of at least 2 but potentially as much as 50. Based on this measured capacitance difference, the various distances between different skin portions (e.g., valleys 102 and ridges 101) can be computed and mapped to a 3D topology of the skin.

In some examples, a fingerprint scanning system 109 can represent an optical scanner 104b. In such cases, the pixels 106b sense light that scatters off of the skin. This scattered light originates from a light source (e.g., a light emitting diode (LED)) that may be located beneath the backplane 105, as illustrated, or may originate from a light source that is coming in from the side, coming in from the side and guided by the protective cover 107, or coming in from the side but entering the skin first and then scattering down to the sensor pixels 106b. In some implementations, the backplane 105 is optically transparent at the illumination wavelengths of operation and transmits the light from the light source through the gaps between pixels and electronics present in the optical scanner.

Example rays 110a and 110b of the illumination light are shown. In some cases, the light ray 110a strikes the ridge 101 of the skin and creates scattered light 111a. Some of the scattered light 111a is detected by the one or more of the sensor pixels 106b. The light ray 110b can strike the valley 102 of the skin and also scatter with some of the scattered light 111b being detected by one or more of the sensor pixels 106b. Since the scattering point on the skin for the ridge 101 might be physically closer by an order of magnitude to the sensor pixel 106b than the scattering point for the valley 102 and because skin is a fairly Lambertian scatterer, the optical scanner 104b can detect a stronger optical signal coming from the ridges 101 than the valleys 102 of the skin. In this way, one or more processors of the fingerprint scanning system 108 can receive the optical signal values from the sensor pixels 106b and can compute pixel intensity values as a measurement based on the optical signal values.

The one or more processors can then generate a raw image of the skin on the basis of the ridges being represented by relatively brighter intensity pixel values than the valleys (e.g., ridges 101 can be relatively bright pixel values in the image and valleys 102 can be relatively dim pixel values). As discussed before, the one or more processors can then compare the raw image against a known image of the skin or use the raw image to generate a 3D topology of the skin and compare the generated 3D topology against a known 3D topology of the skin. If a difference between the known and generated 3D topology or image is below a threshold, the one or more processors can grant access to the secure resource. In some cases, the processors can generate a record by storing the raw image of the skin in association with an identity of a person. Any other suitable operation can be performed using the raw image of the skin as will be apparent to those skilled in the art.

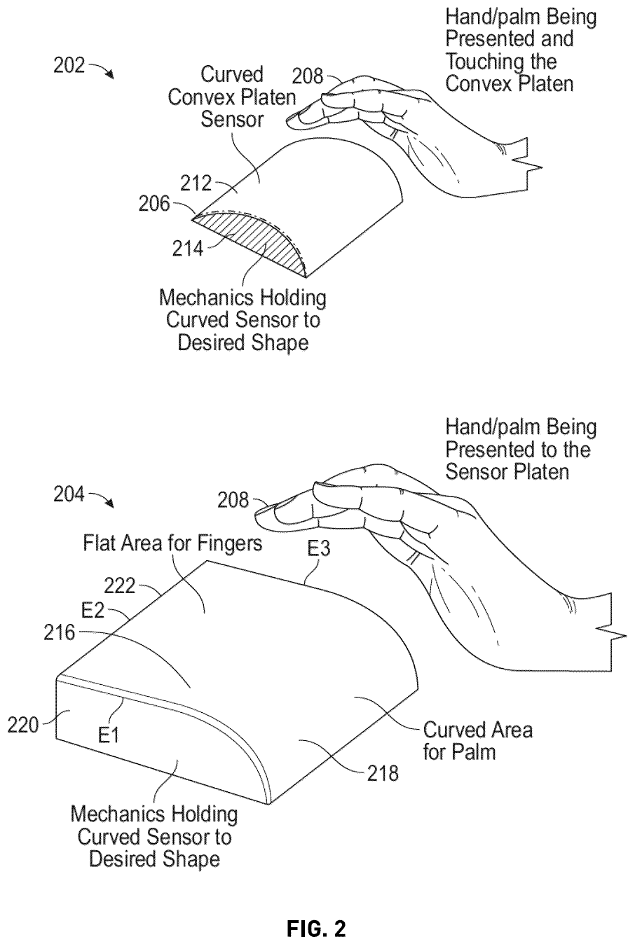

FIG. 2 illustrates different configurations of a flexible pixelated sensor array, according to some examples. Specifically, FIG. 2 illustrates different configurations of a flexible pixelated sensor array that addresses the technical challenges of capturing biometric features from naturally curved anatomical features.

A first configuration diagram 202 includes a curved convex platen sensor that has a flexible pixelated sensor array 206 shaped into a non-planar configuration. The flexible pixelated sensor array 206 includes sensor pixels arranged to detect signal differences between skin ridge contact locations and skin valley locations, similar to the way in which the sensor pixels of the fingerprint scanning system 108 or 109 perform the scans. Namely, the flexible pixelated sensor array 206 can implement some or all of the functionality of the fingerprint scanning system 108 or 109. Any discussion pertaining to fingerprint scanning system 108 is similarly applicable to fingerprint scanning system 109.

The curved convex platen sensor including the flexible pixelated sensor array 206 includes a curved surface 212 and a flat surface 214 oriented at different angles relative to each other. The curved surface 212 is configured to ergonomically conform to the palm and fingers of the hand 208, while the flat surface 214 is positioned at an angle that naturally accommodates thumb placement when the hand grips the sensor. When a user places their hand 208 against the curved surface 212, the thumb naturally aligns with and can be placed on the flat surface 214 due to the approximately 45-degree rotation of the thumb relative to the fingers when the hand is in a natural position.

This configuration addresses the anatomical reality that when fingers are placed flat, the thumb naturally rotates approximately 45 degrees. The rigid structure (which can, in some cases, be flexible or partially rigid and/or coated with a foam layer or have springs attached to sheet material) supports both the curved surface 212 and flat surface 214 while allowing partial compliance to pressure from hand contact. This partial compliance helps ensure good contact between the skin and sensor surface across both the curved and flat portions. During a single hand placement, the flexible pixelated sensor array can capture the fingerprints from the fingers contacting the curved surface 212 while simultaneously capturing the thumbprint from the thumb contacting the flat surface 214.

While maintaining this single hand position, the flexible pixelated sensor array 206 may sequentially capture images of the fingers on the curved surface 212 and the thumb on the flat surface 214 until sufficient quality images are acquired, providing a simultaneous capture experience from the user's perspective without requiring hand repositioning. This ergonomic configuration eliminates the need for separate thumb scanning steps or additional processing to correct rotated, distorted thumb images that occur with traditional flat platen scanners. The orientation of the flat surface 214 relative to the curved surface 212 enables capture of an unrotated thumbprint in its natural position while maintaining comfortable hand placement.

FIG. 2 also includes a second configuration diagram 204 which shows a flexible pixelated sensor array 222 with a flat surface 216 and a curved surface 218 for palm contact and a flat surface 220 for finger contact. The flat surface 220 can also be for thumb contact scanning or can be just a mechanical support and only include the sensitive areas, such as the flat surface 216 and/or the curved surface 218. The curved surface 218, flat surface 216, and flat surface 220 are oriented at different angles and supported by mechanics (e.g., a rigid structure) that maintain the desired shape. The ergonomic design of the second configuration diagram 204 includes edges E1, E2, and E3 allowing individual fingers to be rolled from the edges towards the flat surface 216 while maintaining the curved surface 218 for palm placement. This allows simultaneous capture of palm prints and fingerprints during a single hand placement without requiring the user to reposition their hand for the initial capture. For clarity, one skilled in the art will appreciate that the rolling of a finger is not an instantaneous process and may require multiple images taken of the fingerprint as the finger “rolls.” Further, movement of the hand will generally be required to roll its fingers. Thus, the simultaneous capture of the palm prints and fingerprints may occur during the portion of the rolling where the palm is flat.

The flexible pixelated sensor array 206 or 222 can be fabricated using TFT technology on ultrathin glass or plastic substrates. For glass implementations, ultrathin glass sheets approximately 100 μm thick with a minimum bend radius of 90 mm can be used, or 30 μm glass sheets with minimum bend radius of a few millimeters. Alternative substrate materials include PEN or PET sheets.

During manufacturing, the thin flexible backplane with TFT pixels can be temporarily supported by a thicker backplane and then separated via heat and/or solvents after TFT processing. The pixels of flexible pixelated sensor array 206 or 222 can be configured to detect optical signals, electrical signals, capacitive signals, impedance signals, or ultrasonic signals to identify the differences between skin ridge contact locations and valley locations. This direct detection eliminates the need for complex optical systems or moving parts.

For integration into a product, the flexible sensor array can be supported by either rigid supports or flexible mechanical supports. The flexible supports allow a certain amount of compliance to enable the sensor surface to better match the curvature of the presented skin topology under pressure. The ergonomic configuration addresses the natural anatomy of the human hand, particularly accounting for how the thumb rotates approximately 45 degrees when fingers are placed flat. This allows capture of unrotated, undistorted thumb prints simultaneously with other fingerprints during a single hand placement.

The mechanical supports maintain the non-planar shape while allowing partial compliance to pressure from hand contact. This partial compliance helps ensure good contact between the skin and sensor surface across the entire scanning area without requiring external pressure application. When a user places their hand 208 on the flexible pixelated sensor array 222, the system can capture multiple biometric features during a single hand placement. While the user maintains this single position, the system may sequentially capture images of different portions (like fingers, thumb, and palm) until sufficient quality images are acquired for all desired portions, providing a simultaneous capture experience from the user's perspective.

In some examples, processing circuitry can control the flexible pixelated sensor array 222 in several different capture modes. For simultaneous full capture mode, the processing circuitry activates all pixels across both the curved surface 218 and flat surface 220 to capture palm prints and fingerprints during a single hand placement. The pixels simultaneously detect signal differences between skin ridge contact locations and skin valley locations through optical, electrical, capacitive, impedance, or ultrasonic sensing.

In sequential capture mode, while the user maintains a single hand position, the processing circuitry can activate different portions of the sensor array in sequence. For example, the processing circuitry may first activate pixels on the curved surface 218 to capture the palm print and fingerprints, then activate pixels on the flat surface 220 to capture individual fingers. This sequential activation continues until sufficient quality images are acquired for all desired portions.

For rolled fingerprint capture, the processing circuitry selectively activates pixels that comprise some or all of flat surface 216. For example, certain certifications, e.g., FBI certification, may require a rolled area of 1.5″ tall and 1.6″ wide. Activating a larger area would allow more flexibility for finger placement on flat area 216, but activating a smaller area and having it track the rolling motion of the finger is also an option. The activation area location of pixels within flat surface 216 may depend upon the direction from which the finger is being placed on flat surface 216 (e.g., is it approaching from edge E1, E2, or E3). The system can capture multiple image samples during the rolling motion to ensure complete nail-to-nail fingerprint capture. The processing circuitry can also implement a hybrid capture approach where some portions of the sensor array remain continuously active while others are activated sequentially. For example, in the rolling of fingers, a sparse array of pixels in flat surface 216 may be activated to detect where a finger is being placed. Once that initial placement location is determined, a dense array of pixels, e.g., all pixels within the area that the finger touches the sensor, may be activated, with the boundary of this dense array moving as it tracks the motion of the finger as it is rolling across at least a portion of flat area 216.

When capturing thumbprints, the processing circuitry can activate specific portions of the flat surface 220 while maintaining activation of the curved surface 218 for palm contact. This allows capture of unrotated thumbprints without requiring the user to change their grip position. The system may process these captured images using geometric correction algorithms to account for the sensor's curved surfaces. However, for the case where curved surface 218 is a portion of a cylinder or a similar convex shape wherein one axis of the 2D pixelated sensor array always sees a straight unbent line cross-section, no geometrical correction may be required. From the user's perspective, these different activation patterns and capture sequences may appear as simultaneous capture as only a single hand placement is required. The processing circuitry manages the pixel activation timing and image acquisition to optimize capture quality while maintaining an ergonomic user experience that eliminates the need for multiple hand repositioning steps.

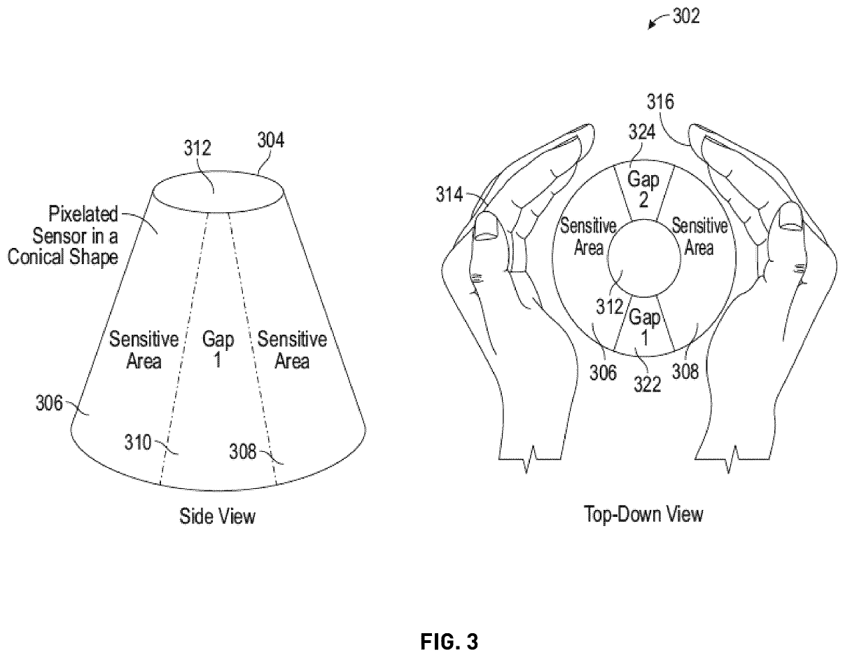

FIG. 3 illustrates another configuration of a flexible pixelated sensor array, according to some examples. Specifically, FIG. 3 illustrates a third configuration diagram 302 showing different configurations and manufacturing considerations for flexible pixelated sensor array 304, particularly focusing on pixel layout options for conical implementations.

The flexible pixelated sensor array 304 includes a first sensitive area 306 and a second sensitive area 308 separated by one or more gaps 310 (also represented as first gap 322). The first sensitive area 306 and the second sensitive area 308 (though more sensitive areas can be included) are configured to capture biometric features from two hands (e.g., first hand 314 and second hand 316) during a single hand placement, with the gap 310 accommodating ergonomic hand placement.

In some examples, a flat surface 312 provides an area for thumb placement of one or more thumbs, while the first hand 314 and the second hand 316 can be positioned on the first sensitive area 306 and second sensitive area 308. The configuration includes optional gaps 322 and 324 between the sensitive areas to facilitate ergonomic positioning. The separation between the sensitive areas may correspond to approximately shoulder width to accommodate comfortable simultaneous placement of both hands. This shoulder-width separation allows users to position their hands naturally without straining their shoulders or arms, which is particularly important for larger individuals or those who may be overweight, as bringing the hands too close together can cause discomfort across the shoulders. The gaps 322 and 324 provide additional spacing to ensure the hands can be positioned at comfortable angles relative to each other while maintaining proper contact between the skin and the sensitive areas 306 and 308. This ergonomic configuration enables simultaneous capture of biometric features from both hands during a single placement without requiring awkward or strained positioning that could affect the quality of the captured images. Alternatively, smaller gaps 322 and 324 may be desired for reasons of reducing packaging volume of the scanner or the accommodation of individuals that are handcuffed as in some law enforcement use cases where the subject cannot stretch their hands apart at shoulder width. Further, it is understood that gaps 322 and 324 are optional and one or both may not be present and sensitive areas 306 and 308 may comprise a single addressable sensitive area where all or a subset or multiple subset of which may have pixels that are activated and ready to capture images with. It is further understood that the flat area 312 may not be an active area and that the capture of a rotated thumb or no thumb at all may be sufficient for certain use cases.

The left side of the third configuration diagram 302 represents a side view of the conical shape configuration of the flexible pixelated sensor array 304. The right side of the third configuration diagram 302 represents a top-down view of the conical shape configuration of the flexible pixelated sensor array 304 when first hand 314 and second hand 316 are placed on the flexible pixelated sensor array 304. Any mention of the flexible pixelated sensor array in this description can be functionally implemented using the fingerprint scanning system 108 or 109. By way of example, two separate sensors (first sensitive area 306 and second sensitive area 308) may be wrapped around a cone shape, each one designed to capture the print of a separate hand. If the separate flexible sensors can be tiled with sufficient precision, then the seam between the two sensors can span across a single finger or hand. Alternatively, a single sensor can be fabricated that wraps around the conical mechanical support structure such that only a single gap (either gap 324 or 322) or no gap is present.

In some examples, the processing circuitry can control the flexible pixelated sensor array 304 in several capture modes to accommodate the dual-hand conical configuration. For full simultaneous capture, the processing circuitry activates all pixels across both sensitive areas 306 and 308 as well as the flat surface 312 to capture palm prints, fingerprints, and thumbprints from both hands during a single placement. The pixels in each area simultaneously detect signal differences between skin ridge contact locations and valley locations through optical, electrical, capacitive, impedance, or ultrasonic sensing methods.

In sequential capture mode, while users maintain their hands in a single comfortable shoulder-width position, the processing circuitry can activate different portions in sequence. For example, the processing circuitry may first activate the first sensitive area 306 to capture one hand's features, then activate the second sensitive area 308 for the other hand, followed by the flat surface 312 for thumbprints. This sequential activation continues until sufficient quality images are acquired from all areas. The processing circuitry can also implement zone-based capture where specific portions of each sensitive area are activated based on hand positioning.

For instance, it may activate the upper portions of areas 306 and 308 for finger capture while separately activating lower portions for palm prints. The flat surface 312 can be selectively activated for capturing unrotated thumbprints without requiring users to adjust their grip. When implementing the design with separate sensors for each sensitive area, the processing circuitry coordinates capture timing between the tiled sensors. The seam between sensors can span across a single finger or hand, requiring precise synchronization of pixel activation and image capture between the separate sensor arrays. Alternatively, the sequential activation may involve the activation of areas 306 and 308 with the single placement of two hands, the sequential activation of areas 306 and then 308 with the placement of two hands but at separate times and the activation of area 312 for purpose of rolls or the placement of one or two simultaneous flat thumbs. Still alternatively, area 312 is not sensitive and the capture of thumbs is not required or the capture of a rotated thumb using areas 306 and/or 308 is sufficient for the use-case security scenario.

From the user's perspective, these different activation patterns and capture sequences appear as simultaneous capture since only a single hand placement is required. The processing circuitry manages the pixel activation timing and image acquisition across all sensitive areas to optimize capture quality while maintaining an ergonomic user experience that eliminates the need for multiple hand repositioning steps.

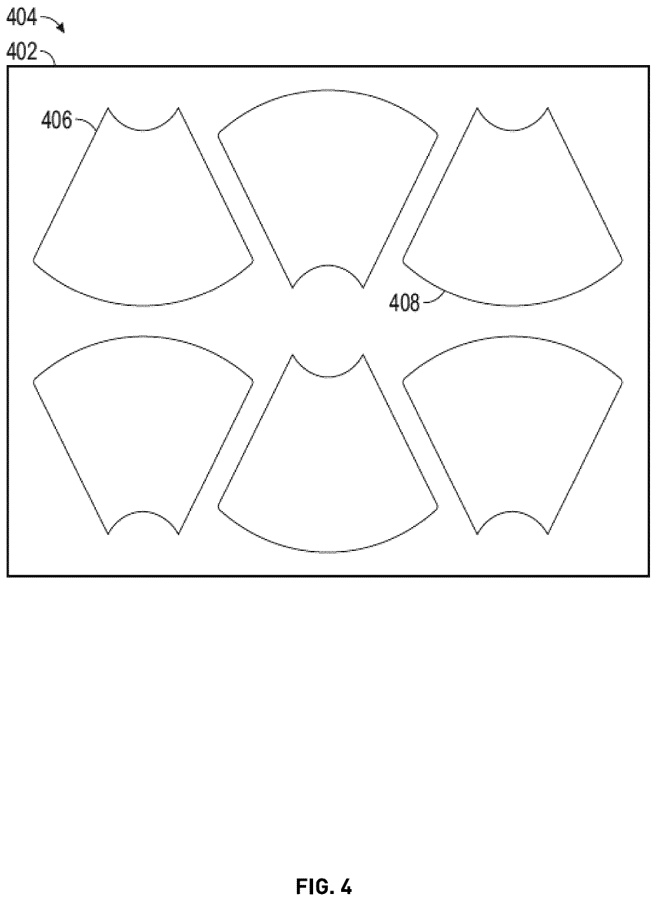

FIG. 4 illustrates a sensor array fabrication diagram 404, according to some examples. Specifically, in order to fabricate the conical shape configuration shown in FIG. 3, a flexible substrate 402 can be used to fabricate various portions of the flexible pixelated sensor array 304 and then assembled together into the conical shape.

The sensor array fabrication diagram 404 in FIG. 4 shows a first flexible pixelated sensor array 406 and a second flexible pixelated sensor array 408 arranged on the flexible substrate 402 during manufacturing to maximize the number of sensors that can be processed on a single backplane substrate. The flexible substrate 402 can be fabricated using TFT technology on ultrathin glass approximately 100 μm thick with a minimum bend radius of 90 mm, or alternatively using 30 μm glass sheets with minimum bend radius of a few millimeters. Other substrate options include PEN or PET sheets.

During manufacturing, the thin flexible backplane containing the TFT pixels is temporarily supported by a thicker backplane and then separated via heat and/or solvents after the TFT processing steps have concluded. This allows the precise patterning of pixels while the substrate is flat before shaping it into the final conical configuration. The sensor array portions (e.g., first flexible pixelated sensor array 406 and second flexible pixelated sensor array 408, as well as many other pixelated sensor arrays of the same or different shapes) are patterned with pixels arranged to detect signal differences between skin ridge contact locations and skin valley locations. These pixels can be configured to detect optical signals, electrical signals, capacitive signals, impedance signals, or ultrasonic signals.

The first flexible pixelated sensor array 406 and second flexible pixelated sensor array 408 are designed to be separated from the flexible substrate 402 after fabrication and assembled together to form the conical shape configuration shown in FIG. 3. This arrangement allows for efficient manufacturing while enabling the final assembly to include separate sensitive areas with appropriate gaps for ergonomic hand placement. The first flexible pixelated sensor array 406 and second flexible pixelated sensor array 408 are arranged on the flexible substrate 402 in a tiling pattern that maximizes the number of sensors that can be processed on a single backplane substrate.

During manufacturing, multiple sensors can be arranged and patterned on the same substrate to make efficient use of the fabrication process. The layout is optimized by arranging the sensor portions to account for the final conical shape requirements while minimizing unused substrate area. This includes positioning the first flexible pixelated sensor array 406 and second flexible pixelated sensor array 408 (and other sensors) to ensure proper dimensions for achieving the desired conical configuration when assembled, while maximizing the number of complete sensor arrays that can be fabricated from a single substrate. In some cases, the pixels are patterned in a regular grid, where the flexible substrate will be shaped into the non-planar configuration. In some cases, there will be pixels extending beyond the boundaries where a hand is expected to be placed, which will better allow for capturing the full hand. This approach ensures that only complete, functional pixels are included in the final sensor array while maximizing the usable area of the flexible substrate 402. This manufacturing approach allows for efficient mass production while maintaining the precise dimensional requirements needed for proper biometric capture functionality.

When assembling the conical configuration, the sensor array portions can be supported by either rigid supports or flexible mechanical supports that allow a certain amount of compliance to enable the sensor surface to better match the curvature of the presented skin topology under pressure. The layout of portions of first flexible pixelated sensor array 406 and second flexible pixelated sensor array 408 on the flexible substrate 402 is optimized to maximize manufacturing yield while ensuring each portion has the correct dimensions to achieve the desired conical shape when assembled. This efficient arrangement of multiple sensors on a single substrate helps reduce manufacturing costs.

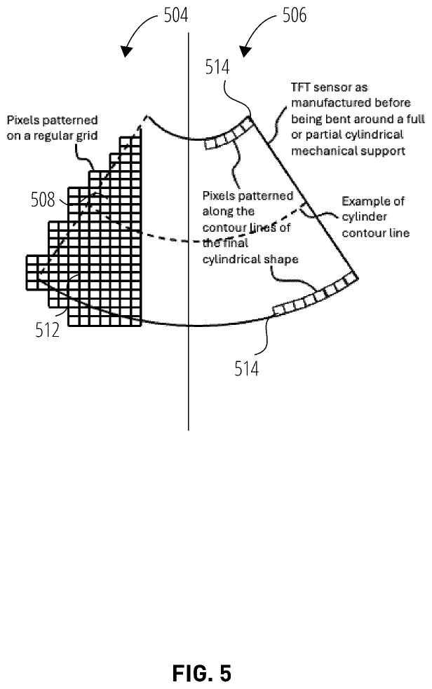

In some cases, as shown in FIG. 5, the pixels of each first flexible pixelated sensor array 406 and second flexible pixelated sensor array 408 are patterned in a regular grid during manufacturing, where the flexible substrate will be shaped into the non-planar configuration. The pixels in the regular grid are made smaller than the final desired biometric image resolution to enable oversampling when the pixels are remapped to account for the non-planar configuration. The patterning of the pixels in a regular grid may result in the effect of certain sensors along the edges of the main sensing area only partially being contained within the sensing area, but this does not impact the functionality of the sensors.

FIG. 5 illustrates a sensor array fabrication diagram, according to some examples. Specifically, FIG. 5 illustrates two alternative approaches for pixel layout and arrangement in the flexible pixelated sensor array 304 for a conical shape configuration. The left side (first pixel design 504) shows pixels patterned on a regular rectangular grid as manufactured before being bent around a conical mechanical support. This layout results in some edge sensor pixels where the regular grid intersects with the edges of the curved configuration.

Inner sensor pixels 512 form the main active sensing area in the regular grid pattern. These pixels are arranged to detect signal differences between skin ridge contact locations and skin valley locations through optical, electrical, capacitive, impedance, or ultrasonic sensing. While pixel design 504 may result in small areas lacking coverage, this is mitigated by having the pixel grid extend beyond the main active sensing area. The main active sensing area may be demarked by a bezel or a printed image to assist the user in positioning the hand within the area.

The right side (second pixel design 506) demonstrates an preferred arrangement where complete edge sensor pixels 514 are patterned along the contour lines of the final conical shape. This approach allows pixels to be placed precisely along the edges without creating areas not covered. However, the second pixel design 506 can present manufacturing challenges since it requires placing pixels along non-linear paths.

Current photolithographic steppers are restricted to an x-y geometry that may need to remain constant for a given wafer or plate being patterned. Due to these manufacturing limitations, the first pixel design 504 with a regular rectangular grid is more cost-effective to produce, despite resulting in some edge pixels. Depending upon the difference between the radius of curvature at the top of the cone versus the bottom, the distance between the two arcs and the size of the pixels used, then potentially no or minimal geometrical correction is required to achieve the “unwrapped” friction ridge image required for biometric processing.

The sensor pixels 508 in both designs can be fabricated on a thin flexible backplane that is temporarily supported by a thicker backplane during manufacturing. After TFT processing is complete, the sensor array can be separated from the support structure and shaped into the desired conical configuration.

When using the regular grid approach of first pixel design 504, image processing algorithms may be used to create properly mapped biometric images that account for the geometric distortion introduced by shaping the flat, fixed 2D grid array of pixels into a curved configuration.

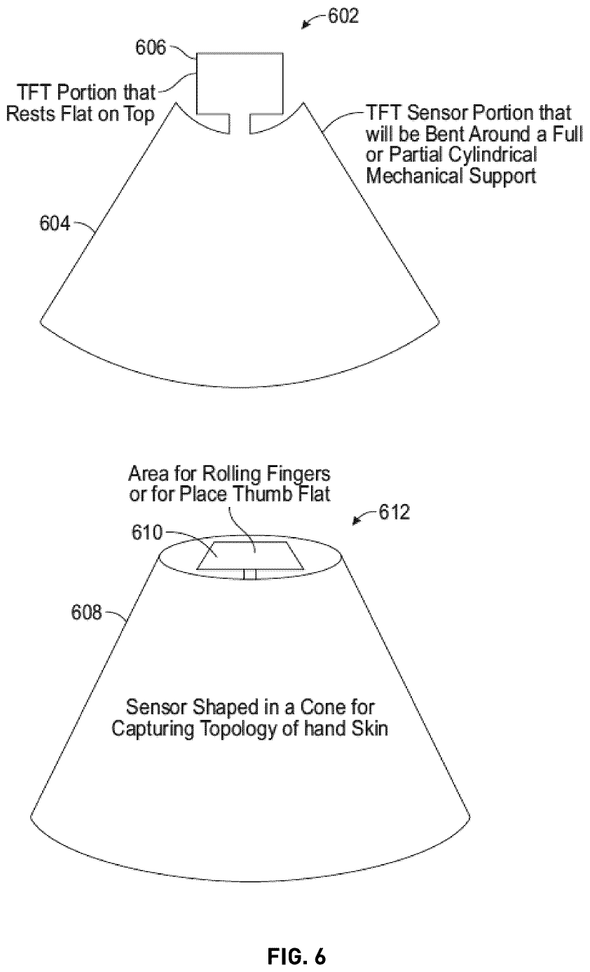

FIG. 6 illustrates a sensor array fabrication diagram and another configuration of the flexible pixelated sensor array, according to some examples. Specifically, FIG. 6 illustrates a sensor array fabrication diagram 602 showing how a flexible pixelated sensor array (e.g., for the fourth configuration diagram 612) can be configured into a conical shape with specialized areas for different types of biometric capture.

The sensor array fabrication diagram 602 shows a second portion of flexible pixelated sensor array 606 that will rest flat on top of the conical structure (or can be raised at some angle relative to the conical shape), and a first portion of flexible pixelated sensor array 604 that will be bent around a full or partial conical mechanical support. The fourth configuration diagram 612 creates a sensor with a curved portion 608 for capturing hand/palm topology and a flat portion 610 specifically designed for finger rolling or flat thumb placement.

The fourth configuration diagram 612 demonstrates how the sensor portions are assembled into a cone shape for capturing topology of hand skin. The flat portion 610 on top of the cone provides an area specifically designed for rolling individual fingers or placing the thumb flat while maintaining the conical shape for palm and finger placement. During manufacturing, the flexible pixelated sensor array is fabricated on a thin flexible backplane using TFT technology. The array includes pixels arranged to detect signal differences between skin ridge contact locations and skin valley locations through optical, electrical, capacitive, impedance, or ultrasonic sensing.

The first portion of flexible pixelated sensor array 604 and second portion of flexible pixelated sensor array 606 (which can be connected to each other or physically separate parts) are patterned on the same flexible substrate during manufacturing to maximize production efficiency.

After TFT processing, the portions are separated from the temporary support backplane and shaped into the final conical configuration. The flat top surface may accommodate nail-to-nail fingerprint capture by enabling users to roll individual fingers across the surface while maintaining the conical shape for palm and finger placement. This allows complete capture of rolled fingerprints without requiring a separate scanning device. Alternatively or in addition, flat portion 610 may accommodate scanning of thumbs that are placed at same time as hands on curved portion 608. Still alternatively or in addition, flat portion 610 may provide scanning of thumbs or fingers placed flat one or more at a time.

When assembled, the mechanical structure supports both the curved portion 608 and flat portion 610 while allowing partial compliance to pressure from hand contact. This compliance helps ensure good contact between the skin and sensor surface across both the curved and flat portions during biometric capture. The configuration enables simultaneous capture of palm prints and fingerprints during a single hand placement, with the option to capture rolled prints on the flat top surface.

In some examples, a user approaches the device and places their hand around the conical curved portion 608, with their palm and fingers naturally conforming to the cone shape. The curved surface ergonomically matches the natural cupping of the palm while allowing the fingers to maintain contact along the conical surface. The flat portion 610 on top of the cone remains accessible for two key functions: thumb placement and finger rolling. For initial capture, the user may place their thumb flat on the top surface while their palm and other fingers maintain contact with the conical portion if hand biometric capture is desired without a thumb print that is rotated. For rolled fingerprint capture, the user places their fingers one at a time on flat portion 610 and either on their own or with assistance rolls their fingers. Additional options are that the user may place one thumb or both thumbs on flat portion 610 for scanning without touching curved portion 608.

The flat surface may additionally accommodate complete nail-to-nail fingerprint capture as the user and/or operator rolls each finger from one edge to the other. The mechanical structure's optional partial compliance allows the sensing surfaces to slightly conform under pressure, ensuring consistent contact between the skin and sensor across both the curved and flat portions. The TFT pixels detect ridge and valley patterns through optical, electrical, capacitive, impedance, or ultrasonic sensing methods.

During a single-hand placement session, the system can capture: a complete palm print from the conical portion 608; flat fingerprints from all four fingers on the conical surface; a rotated thumb on the conical surface, an unrotated thumbprint from the flat top portion 610; and/or rolled prints from individual fingers using the flat top surface. The ergonomic design allows users to maintain comfortable hand positioning throughout the capture sequence, while the combination of curved and flat surfaces enables complete biometric capture without requiring separate scanning devices and limited, if any, hand repositioning.

In some examples, processing circuitry can control the flexible pixelated sensor array in several capture modes for the conical configuration. In full simultaneous capture mode, the processing circuitry activates all pixels across both the curved portion 608 and flat portion 610 to capture palm prints, fingerprints, and thumbprints during a single hand placement. The pixels simultaneously detect signal differences between skin ridge contact locations and valley locations through optical, electrical, capacitive, impedance, or ultrasonic sensing methods.

For sequential capture while maintaining a single-hand position, the processing circuitry can activate different portions in sequence. For example, it may first activate pixels on the curved portion 608 to capture the palm print and initial fingerprints, then activate pixels on the flat portion 610 to capture the thumb or rolled fingerprints. This sequential activation may repeat until sufficient quality images are acquired from all desired portions. Alternatively, it remains a single sequential process where for example, curved portion 608 is activated first and stays activated until a sufficient quality four fingers, palm, or whole hand print either with or without a rotated thumb is captured. Curved Portion 608 may be disactivated and flat portion 610 may be activated to acquire the flat thumb or with repositioned hand, the rolls of one or more of the fingers and/or thumb. Capturing of rolled prints may be performed according to prior art where multiple images are captured during a digit's motion. This image stack is processed to identify features of the fingerprint in each image and determine the boundary of new print information across the multiple images and then correspondingly stitch together to arrive at a composite image representing the desired rolled print.

The processing circuitry can implement zone-based capture where specific portions of each sensor area are activated based on the type of capture being performed. For instance, depending upon the hand being present, it may activate the left or right portions of the curved portion 608 for finger capture while separately activating right or left portions for palm prints. The flat portion 610 can be selectively activated for capturing either unrotated thumbprints or rolled fingerprints. When implementing the design with separate sensor portions (604 and 606), the processing circuitry coordinates capture timing between the connected or physically separate sensor arrays.

This requires precise synchronization of pixel activation and image capture between the sensor portions to ensure seamless biometric capture across the entire surface. The system processes these captured images using geometric correction algorithms to account for the conical surface shape. From the user's perspective, these different activation patterns and capture sequences appear as simultaneous capture since only a single hand placement is required. The processing circuitry manages the pixel activation timing and image acquisition across all portions to optimize capture quality while maintaining an ergonomic user experience that eliminates the need for multiple hand repositioning steps.

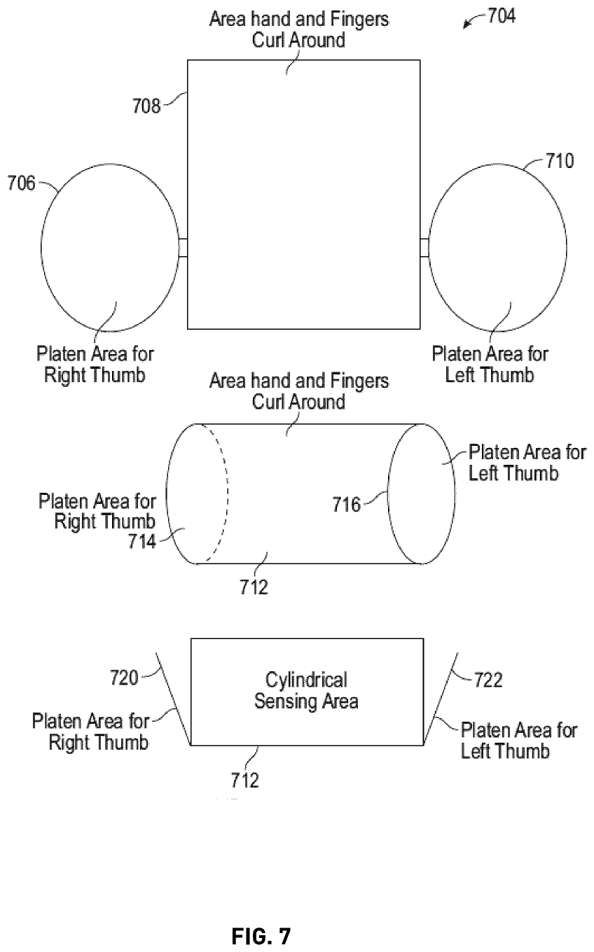

FIG. 7 illustrates a sensor array fabrication diagram and another configuration of the flexible pixelated sensor array, according to some examples. Specifically, FIG. 7 illustrates a cylindrical sensor configuration (e.g., fifth configuration diagram 704) with specialized areas for capturing biometric data from one or two hands simultaneously.

The fifth configuration diagram 704 includes a cylindrical sensing area (e.g., a curved area 712) that serves as the main curved surface around which hands and fingers curl. This cylindrical curved area 712 is flanked by multiple flat portions strategically positioned for thumb placement.

Specifically, the configuration includes a first platen area (e.g., first sensor portion 706) for placing a right thumb and a second platen area (e.g., third sensor portion 710) for placing a left thumb for the case of a user's palm extend outward. For case where the user's palm is facing up or back towards the user, then portion 706 would be instead better suited ergonomically for the left thumb and portion 710 for the right thumb. The first sensor portion 706 can be fabricated on a flexible substrate and placed on a rigid surface, creating the first flat portion 714. Similarly, the third sensor portion 710 can be fabricated on the same or different flexible substrate, and placed on the same rigid surface to create the second flat portion 716. One thumb can be comfortably placed on the first flat portion 714 while another thumb is placed on the second flat portion 716. The rest of the hand and fingers can curl around the curved area 712, which can be created by fabricating the second sensor portion 708 on the same or different flexible substrate. This allows the flexible pixelated sensor array to capture an image of two palm prints, eight fingers, and two thumbs with a single placement of the hands.

These platen areas are positioned at angles that naturally accommodate thumb placement when the hands grip the cylindrical portion. The first flat portion 714 and second flat portion 716 provide additional surfaces for finger placement or rolling. When a user wraps their hands around the cylindrical curved area 712, their thumbs can naturally rest on the angled platen areas without requiring rotation or awkward positioning. The configuration enables simultaneous capture of palm prints and fingerprints during a single hand placement. In some cases, the first flat portion 714 and the second flat portion 716 can each or both be angled relative to the curved area 712. This creates a first angled flat portion 720 and second angled flat portion 722, specifically designed to capture unrotated thumbprints. This addresses the anatomical reality that when fingers are placed flat, thumbs naturally rotate approximately 45 degrees.

The mechanical structure supports both the cylindrical curved area 712 and the various flat portions while optionally allowing partial compliance to pressure from hand contact. This compliance may ensure good contact between the skin and sensor surface across all portions during biometric capture. From an ergonomic standpoint, the configuration allows users to position their hands at comfortable angles relative to each other while maintaining proper contact with all sensing surfaces.

The angled thumb platen areas eliminate the need for separate thumb scanning steps or additional processing to correct rotated, distorted thumb images that occur with traditional flat platen scanners. The flexible pixelated sensor array used in this configuration is fabricated using TFT technology on a flexible substrate. The pixels are arranged to detect signal differences between skin ridge contact locations and valley locations through optical, electrical, capacitive, impedance, or ultrasonic sensing.

Although a full cylinder is illustrated, in practice a sensor area geometry may be constructed such that it only partially wraps around a cylinder or partial cylinder support mechanics and/or the side thumb platen areas may not necessarily be circular areas but could be other shapes such as rectangular or oval. Further, the side thumb platen areas may be concave in order to partially wrap around the thumb. The sensor is fabricated on a flexible substrate and for the case of the strip connecting sensor areas 706 and 710 to area 708 being thin enough then the mechanical stresses of bending areas 706 and 710 to fit over a concave mechanical support whilst sensor area 708 bends around a convex and substantially cylindrical mechanical support can be minimized. The concave shape of the left and right platen areas has two advantages. First the shape will help guide the user in terms of where the thumb is to be placed and second the shape will enable more of the thumb print to be captures as a human's thumb is naturally convex and not flat.

In some examples, a user approaches the device and places both hands around the cylindrical curved area 712, similar to gripping a large cylinder. The fingers naturally curl around the curved sensing surface while the palms make contact with the cylindrical area. For the right hand, the thumb naturally extends to rest flat against the first angled flat portion 720, while the four fingers maintain contact with the curved area 712. Similarly, the left hand's thumb extends to rest against the second angled flat portion 722, with its four fingers also wrapped around the curved surface. The approximately 45-degree angles of portions 720 and 722 accommodate the natural anatomical positioning of the thumbs relative to the fingers.

During image capture, the flexible pixelated sensor array simultaneously detects the skin topology across all contact surfaces. In one example, the system first captures the palm prints and fingerprints from both hands as they maintain contact with the curved area 712. Concurrently, unrotated thumbprints are captured from the angled flat portions 720 and 722 without requiring the user to reposition their hands. The mechanical structure's optional partial compliance may allow the sensing surfaces to slightly conform to the unique contours of each user's hands, ensuring consistent contact pressure and image quality across all areas. The TFT pixels detect the ridge and valley patterns through either optical, electrical, capacitive, impedance, or ultrasonic sensing methods. The system may process these signals to generate standardized biometric templates for all ten fingers and both palms from this single hand placement or generate a subset of these templates. The ergonomic design allows users to maintain this position comfortably while the system captures multiple image samples if needed to ensure optimal quality. Since the hands are positioned at natural angles relative to each other and the thumbs rest unrotated on the angled surfaces, users can maintain consistent contact without strain during the entire capture sequence.

In some examples, processing circuitry can control the cylindrical configuration's flexible pixelated sensor array in several capture modes. In full simultaneous capture mode, the processing circuitry activates all pixels across the cylindrical curved area 712 and angled flat portions 720 and 722 to capture palm prints, fingerprints, and thumbprints from both hands during a single placement. The pixels simultaneously detect signal differences between skin ridge contact locations and valley locations through optical, electrical, capacitive, impedance, or ultrasonic sensing methods.

For sequential capture while maintaining a single hand position, the processing circuitry can activate different portions in sequence. For example, it may first activate pixels on the curved area 712 to capture palm prints and fingerprints from both hands, then activate pixels on the angled flat portions 720 and 722 to capture unrotated thumbprints. This sequential activation continues until sufficient quality images are acquired from all areas.

The processing circuitry can implement zone-based capture where specific portions of each sensor area are activated based on hand positioning. For instance, it may activate upper portions of the curved area 712 for finger capture while separately activating lower portions for palm prints. The angled flat portions 720 and 722 can be selectively activated for capturing unrotated thumbprints without requiring users to adjust their grip. When implementing the design with separate sensor portions (706, 708, 710), the processing circuitry coordinates capture timing between the connected or physically separate sensor arrays.

From the user's perspective, these different activation patterns and capture sequences appear as simultaneous capture since only a single hand placement is required. The processing circuitry manages the pixel activation timing and image acquisition across all portions to optimize capture quality while maintaining an ergonomic user experience that eliminates the need for multiple hand repositioning steps. The mechanical structure's partial compliance ensures consistent contact pressure and image quality is maintained across all activated sensor areas during the capture sequence.

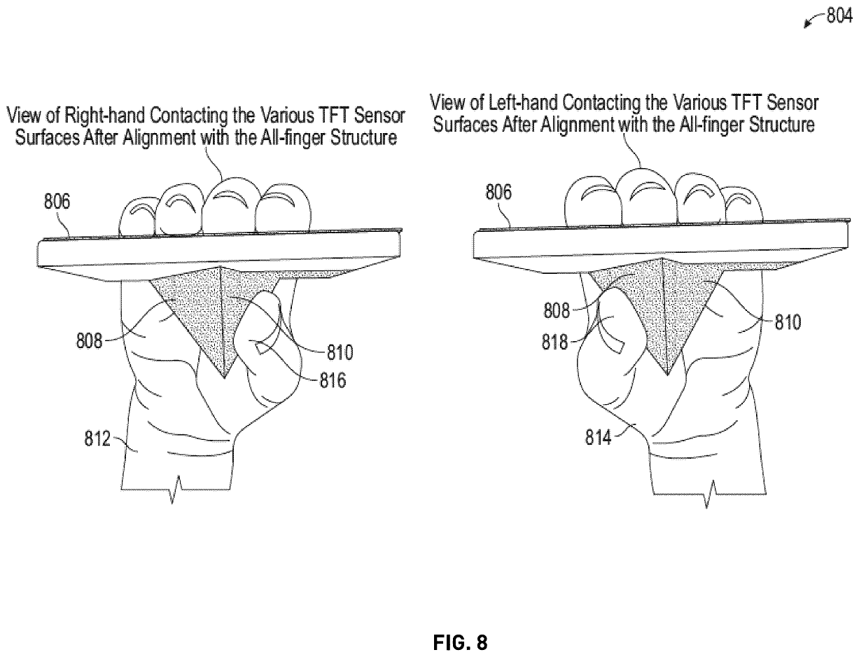

FIG. 8 illustrates another configuration of the flexible pixelated sensor array, according to some examples. Specifically, FIG. 8 illustrates an all-finger scanner configuration (e.g., sixth configuration diagram 804) that enables simultaneous capture of fingerprints from both hands in an ergonomic position. The scanner includes multiple angled surfaces designed to capture fingerprints simultaneously, with a top platen surface (e.g., first sensor surface 806) for capturing four fingers, and angled surfaces (e.g., second sensor surface 808 and third sensor surface 810) forming a 3-sided pyramid feature on the bottom for capturing thumbprints.

In operation, a user can position their right hand 812 with four fingers placed flat on the first sensor surface 806 while the right thumb 816 naturally extends to contact one of the angled pyramid surfaces (e.g., second sensor surface 808). Similarly, they would position their left hand 814 with fingers on the top surface (first sensor surface 806) while the left thumb 818 contacts another angled surface (e.g., third sensor surface 810) of the pyramid.

The pyramid structure's three angled surfaces are specifically designed to allow thumbs from either hand to make flat contact without requiring rotation. This addresses the anatomical reality that thumbs naturally rotate approximately 45 degrees relative to fingers when placed on a flat surface. During capture, the flexible pixelated sensor array simultaneously detects fingerprints from all four fingers on the first sensor surface 806, a thumbprint from the right thumb 816 on one angled surface, and a thumbprint from the left thumb 818 on another angled surface. The configuration allows natural hand positioning similar to holding a book or phone, where fingers grip one side while thumbs wrap around to the other side. The pyramid feature accommodates the natural thumb angle when gripping, eliminating the need to force thumbs into an unnatural flat position.

The TFT sensor array can be fabricated on a flexible substrate that is shaped and adhered to the mechanical support structure to create both the flat top surface and angled pyramid surfaces. This enables a single sensor array to capture all fingers and thumbs simultaneously during one natural hand placement without requiring separate scanning steps or image rotation corrections. Although drawn as flat, the sides of the pyramid may be non-planar for reasons of notifying the user as to where the thumb should be placed as well as to increase the contact area of the thumb and the platen. By way of example the angled sensor surfaces 810 and 808 may be concave and further substantially cylindrical with the axis of the cylinder being substantially parallel to the intended direction the thumb should be placed. Note further that although angle surfaces of the pyramid feature are illustrated as joining in a sharp straight line, in general this intersection of the two sides may be a more gradual transition. In fact, the joint between the two sides may be rounded to provide less mechanical stress on the flexible image sensor.

In some examples, the processing circuitry can control the pyramid configuration's flexible pixelated sensor array in several capture modes. In full simultaneous capture mode, the processing circuitry activates all pixels across the first sensor surface 806 and angled pyramid surfaces 808 and 810 to capture fingerprints from all four fingers and thumb during a single placement. The pixels simultaneously detect signal differences between skin ridge contact locations and valley locations through optical, electrical, capacitive, impedance, or ultrasonic sensing methods.

For sequential capture while maintaining a single hand position, the processing circuitry can activate different portions in sequence. For example, it may first activate pixels on the top surface 806 to capture the four fingerprints from a hand. Once a sufficient quality biometric image of the fingers has been captured, the apparatus may activate pixels on the angled pyramid surfaces 808 and 810 to capture unrotated thumbprints. Note that since the fingers are captured first, the system may determine based upon the fingers captured which hand was scanned (e.g., a left four-finger image will have the shortest finger fingerprint image on the left and for the right four-finger image, this shortest finger fingerprint image will be on the right). Based upon this information, the scanner will activate the appropriate 808 or 810 angled sensor surfaces. Once acceptable biometric data is captured from one hand, the system may ask for the second hand to be presented and repeat the described sequential activation process for this second hand. Also pyramid surfaces 808 and 810 can be scanned to determine if a thumb is present and based on whether 808 or 810 has a thumb fingerprint image the hand sequence can be determined. The 4 fingers from surface 806 can be evaluated to determine if it correlates with the proper hand sequence derived from surfaces 808 and 810.

The processing circuitry can implement zone-based capture where specific portions of each sensor surface are activated based on hand positioning. For instance, it may activate different zones of the first sensor surface 806 to separately capture the fingers from each hand, while selectively activating the angled pyramid surfaces 808 and 810 for capturing unrotated thumbprints without requiring users to adjust their grip. When implementing the design with separate sensor portions for the top and pyramid surfaces, the processing circuitry coordinates capture timing between the connected or physically separate sensor arrays. This requires precise synchronization of pixel activation and image capture between the sensor portions to ensure seamless biometric capture across all surfaces.

The system processes these captured images using geometric correction algorithms to account for the angled pyramid surfaces. From the user's perspective, these different activation patterns and capture sequences appear as simultaneous capture since only a single hand placement in a natural book-holding position is required. The processing circuitry manages the pixel activation timing and image acquisition across all surfaces to optimize capture quality while maintaining an ergonomic user experience that eliminates the need for multiple hand repositioning steps.

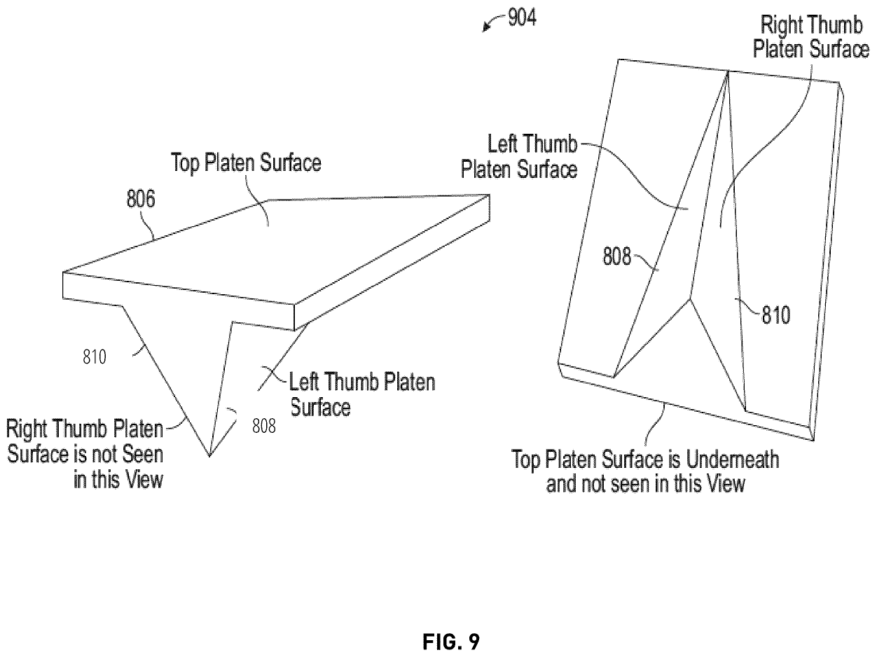

FIG. 9 illustrates another view of the configuration of the flexible pixelated sensor array of FIG. 8, according to some examples. Specifically, FIG. 9 provides additional views of the all-finger scanner configuration (diagram of sixth configuration 904) shown in FIG. 8, specifically illustrating the arrangement of the various platen surfaces. The configuration includes a top platen surface that serves as the main scanning area for capturing fingerprints from eight fingers simultaneously.

Below this, a left thumb platen surface and right thumb platen surface are positioned at angles as part of the pyramid structure. The diagram of sixth configuration 904 shows how the right thumb platen surface is not visible from this particular view angle, while the left thumb platen surface and top platen surface are clearly visible. This arrangement demonstrates how the pyramid structure's angled surfaces are positioned to naturally accommodate thumb placement when users grip the device.

An alternative view shows the configuration from underneath, where the top platen surface is hidden from view but both thumb platen surfaces of the pyramid structure are visible. This view illustrates how the angled surfaces are oriented to enable comfortable thumb placement for either hand while maintaining proper contact for biometric capture. The mechanical structure supports all platen surfaces in fixed positions relative to each other, creating an ergonomic scanning device that accommodates the natural positioning of fingers and thumbs. The flexible pixelated sensor array is shaped and adhered to these surfaces, allowing simultaneous capture of all fingers and thumbs during a single hand placement without requiring rotation or repositioning.

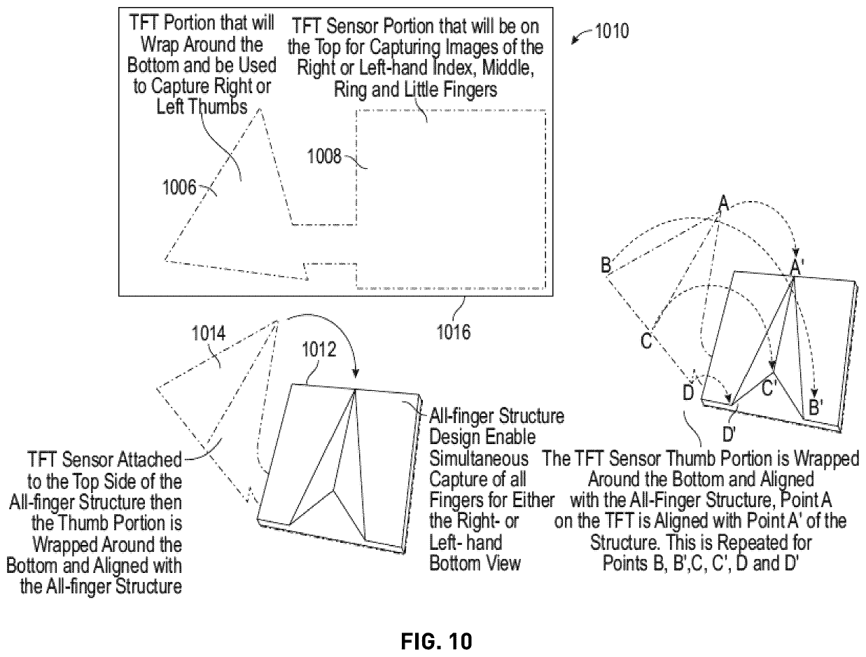

FIG. 10 illustrates a sensor array fabrication diagram for the configuration of FIG. 8, according to some examples. Specifically, FIG. 10 illustrates a sensor array fabrication diagram 1010 showing how the flexible pixelated sensor array is manufactured and assembled for the all-finger scanner configuration.

The sensor array fabrication diagram 1010 shows a TFT sensor portion (first sensor portion 1008) that can be positioned on the top side of the all-finger structure for capturing images of the right or left hand index, middle, ring, and little fingers. A separate TFT portion (second sensor portion 1006) is designed to wrap around the bottom and be used to capture right or left thumbs.

The flexible substrate 1014 containing the TFT sensor array is initially supported by a temporary support 1016 during manufacturing. After fabrication, the TFT sensor is attached to the top side of the all-finger structure support surface 1012 (e.g., rigid structure), then the thumb portion is wrapped around the bottom and aligned with specific alignment points. The alignment process involves matching corresponding points between the TFT sensor and the mechanical structure—point A on the TFT is aligned with point A′ of the structure, point B aligns with B′, point C with C′, and point D with D′.

This precise alignment ensures proper positioning of the sensor array across both the top surface for fingers and the angled pyramid surfaces for thumbs. The bottom view of the all-finger structure shows how it is specifically designed to enable simultaneous capture of all fingers for either the right or left hand. The mechanical structure maintains the proper angles and spacing between the finger and thumb sensing surfaces while providing support for the flexible TFT sensor array. The fabrication approach of using a single flexible substrate that can be shaped and aligned to cover both the top and bottom surfaces helps maximize manufacturing efficiency while ensuring proper sensor positioning for ergonomic biometric capture. This design enables the creation of a unified scanning device that can capture all fingers and thumbs simultaneously during a single hand placement.

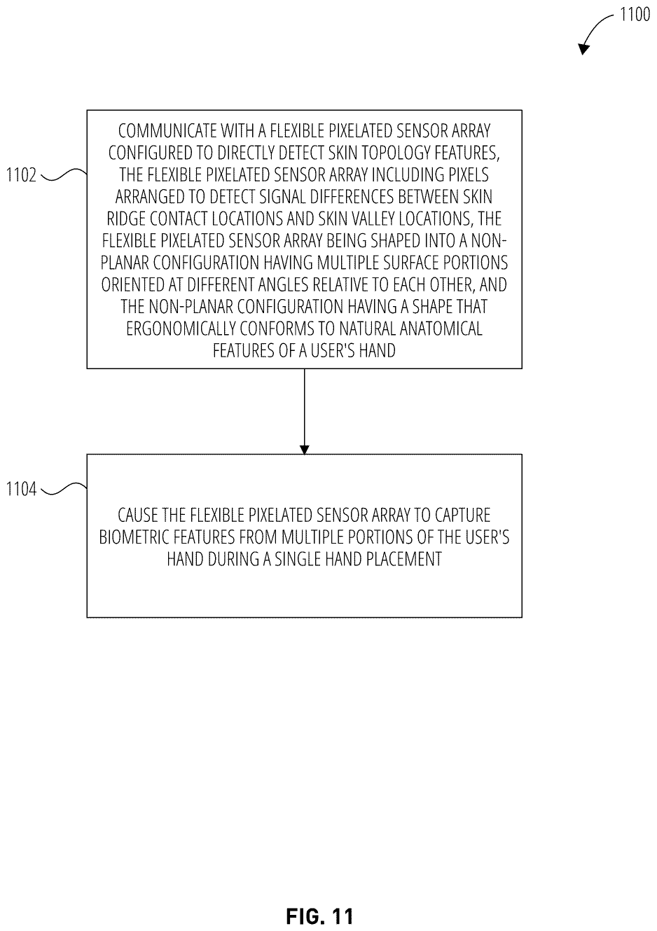

FIG. 11 illustrates a routine 1100 (e.g., method or process) in accordance with some examples. The operations discussed in connection with FIG. 11 can be performed sequentially, in parallel, and in any suitable order. The operations discussed in FIG. 11 can be performed by the fingerprint scanning system 108.

In operation 1102, the fingerprint scanning system 108 communicates with a flexible pixelated sensor array configured to directly detect skin topology features, the flexible pixelated sensor array including pixels arranged to detect signal differences between skin ridge contact locations and skin valley locations, the flexible pixelated sensor array being shaped into a non-planar configuration having multiple surface portions oriented at different angles relative to each other, and the non-planar configuration having a shape that ergonomically conforms to natural anatomical features of a user's hand, as discussed above.

In operation 1104, the fingerprint scanning system 108 causes the flexible pixelated sensor array to capture biometric features from multiple portions of the user's hand during a single hand placement, as discussed above.

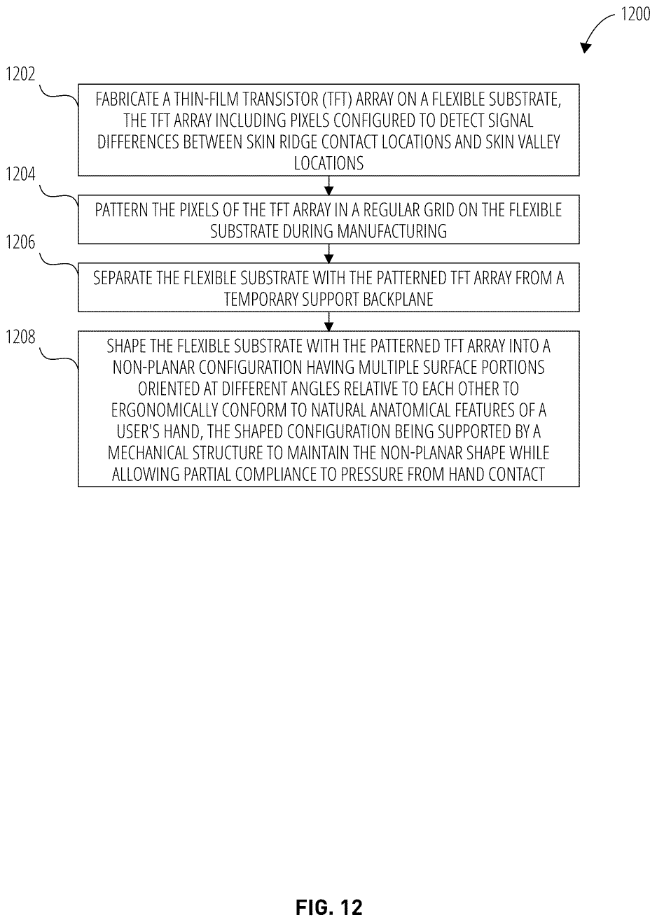

FIG. 12 illustrates a routine 1200 (e.g., method or process) in accordance with some examples. The operations discussed in connection with FIG. 12 can be performed sequentially, in parallel, and in any suitable order. The operations discussed in FIG. 12 can be performed by the fingerprint scanning system 108 or manufacturing device or system.

In operation 1202, routine 1200 fabricates a pixelated sensing array on a flexible substrate, where the pixels are configured to detect signal differences between skin ridge contact locations and skin valley locations. The sensing array may be fabricated using TFT technology or another technology deemed suitable by one skilled in the art.

In operation 1204, routine 1200 patterns the pixels of the TFT array in a regular grid on the flexible substrate during manufacturing.

In operation 1206, routine 1200 separates the flexible substrate with the patterned TFT array from a temporary support backplane.

In operation 1208, routine 1200 shapes the flexible substrate with the patterned TFT array into a non-planar configuration having multiple surface portions oriented at different angles relative to each other to ergonomically conform to natural anatomical features of a user's hand, the shaped configuration being supported by a mechanical structure to maintain the non-planar shape while allowing partial compliance to pressure from hand contact.

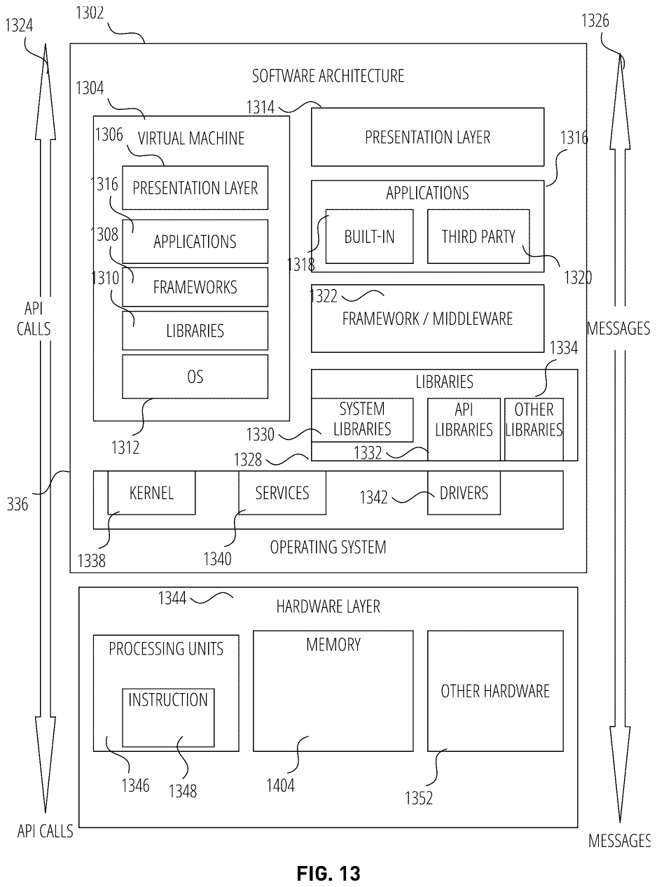

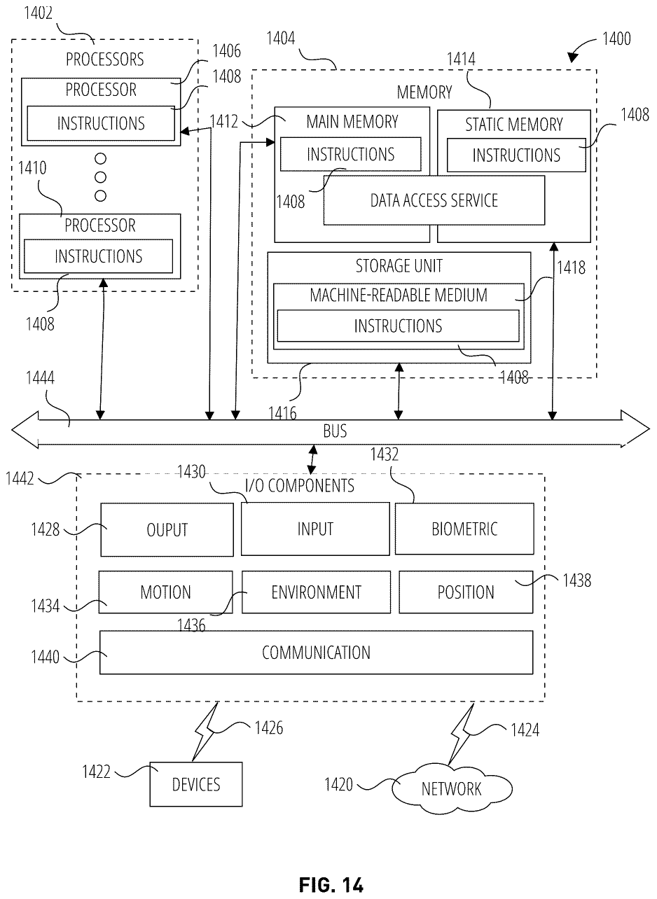

FIG. 13 is a block diagram illustrating an example of a software architecture 1302 that may be installed on a machine, according to some examples. FIG. 13 is merely a non-limiting example of a software architecture, and it will be appreciated that many other architectures may be implemented to facilitate the functionality described herein. The software architecture 1302 may be executing on hardware such as a machine 1400 of FIG. 14 that includes, among other things, processors 1410, memory 1404, and input/output (I/O) components 1442. A representative hardware layer 1344 is illustrated and can represent, for example, the machine 1400 of FIG. 14. The representative hardware layer 1344 comprises one or more processing units 1346 having associated executable instructions 1348. The executable instructions 1348 represent the executable instructions of the software architecture 1302. The hardware layer 1344 also includes memory 1404, which also have the executable instructions 1348. The hardware layer 1344 may also comprise other hardware 1352, which represents any other hardware of the hardware layer 1344, such as the other hardware illustrated as part of the machine 1400.

The instructions 1348 may be transmitted or received over the network using a transmission medium via a network interface device (e.g., a network interface component included in the communication components 1440) and utilizing any one of a number of well-known transfer protocols (e.g., hypertext transfer protocol (HTTP)). Similarly, the instructions 1348 may be transmitted or received using a transmission medium via the coupling (e.g., a peer-to-peer coupling) to the devices. The terms “transmission medium” and “signal medium” mean the same thing and may be used interchangeably in this disclosure. The terms “transmission medium” and “signal medium” shall be taken to include any intangible medium that is capable of storing, encoding, or carrying the instructions 1348 for execution by the machine 1400, and include digital or analog communications signals or other intangible media to facilitate communication of such software. Hence, the terms “transmission medium” and “signal medium” shall be taken to include any form of modulated data signal, carrier wave, and so forth. The term “modulated data signal” means a signal that has one or more of its characteristics set or changed in such a manner as to encode information in the signal.

The terms “machine-readable medium,” “computer-readable medium,” and “device-readable medium” mean the same thing and may be used interchangeably in this disclosure. The terms are defined to include both machine-storage media and transmission media. Thus, the terms include both storage devices/media and carrier waves/modulated data signals.

As used herein, the terms “machine-storage medium,” “device-storage medium,” and “computer-storage medium” mean the same thing and may be used interchangeably in this disclosure. The terms refer to a single or multiple storage devices and/or media (e.g., a centralized or distributed database, and/or associated caches and servers) that store executable instructions and/or data. The terms shall accordingly be taken to include, but not be limited to, solid-state memories, and optical and magnetic media, including memory internal or external to processors. Specific examples of machine-storage media, computer-storage media, and/or device-storage media include non-volatile memory, including by way of example semiconductor memory devices, e.g., erasable programmable read-only memory (EPROM), electrically erasable programmable read-only memory (EEPROM), field-programmable gate arrays (FPGAs), and flash memory devices; magnetic disks such as internal hard disks and removable disks; magneto-optical disks; and CD-ROM and DVD-ROM disks. The terms “machine-storage medium,” “computer-storage medium,” and “device-storage medium” are non-transitory computer-readable media and specifically exclude carrier waves, modulated data signals, and other such media, at least some of which are covered under the term “signal medium.”

In the example architecture of FIG. 13, the software architecture 1302 may be conceptualized as a stack of layers, where each layer provides particular functionality. For example, the software architecture 1302 may include layers such as an operating system 1336, libraries 1328, framework/middleware 422, applications 1316, and a presentation layer 1314. Operationally, the applications 1316 or other components within the layers may invoke API calls API calls 1324 through the software stack and receive a response, returned values, and so forth (illustrated as messages 1326) in response to the API calls 1324. The layers illustrated are representative in nature, and not all software architectures have all layers. For example, some mobile or special-purpose operating systems may not provide a framework/middleware 422 layer, while others may provide such a layer. Other software architectures may include additional or different layers.

The operating system 1336 may manage hardware resources and provide common services. The operating system 1336 may include, for example, a kernel 1338, services 1340, and drivers 1342. The kernel 1338 may act as an abstraction layer between the hardware and the other software layers. For example, the kernel 1338 may be responsible for memory management, processor management (e.g., scheduling), component management, networking, security settings, and so on. The services 1340 may provide other common services for the other software layers. The drivers 1342 may be responsible for controlling or interfacing with the underlying hardware. For instance, the drivers 1342 may include display drivers, camera drivers, Bluetooth® drivers, flash memory drivers, serial communication drivers (e.g., Universal Serial Bus (USB) drivers), Wi-Fi® drivers, audio drivers, power management drivers, and so forth depending on the hardware configuration.

The libraries 1328 may provide a common infrastructure that may be utilized by the applications 1316 and/or other components and/or layers. The libraries 1328 typically provide functionality that allows other software modules to perform tasks in an easier fashion than by interfacing directly with the underlying operating system 1336 functionality (e.g., kernel 1338, services 1340, or drivers 1342). The libraries 1328 may include system libraries 1330 (e.g., C standard library) that may provide functions such as memory allocation functions, string manipulation functions, mathematic functions, and the like. In addition, the libraries 1328 may include API libraries 1332 such as media libraries (e.g., libraries to support presentation and manipulation of various media formats such as MPEG4, H.264, MP3, AAC, AMR, JPG, and PNG), graphics libraries (e.g., an OpenGL framework that may be used to render 2D and 3D graphic content on a display), database libraries (e.g., SQLite that may provide various relational database functions), web libraries (e.g., WebKit that may provide web browsing functionality), and the like. The libraries 1328 may also include a wide variety of other libraries 1334 to provide many other APIs to the applications 1316 and other software components/modules.

The frameworks/middleware 1322 (also sometimes referred to as middleware) may provide a higher-level common infrastructure that may be utilized by the applications 1316 or other software components/modules. For example, the frameworks/middleware 1322 may provide various graphical user interface functions, high-level resource management, high-level location services, and so forth. The frameworks/middleware 1322 may provide a broad spectrum of other APIs that may be utilized by the applications 1316 and/or other software components/modules, some of which may be specific to a particular operating system or platform.

The applications 1316 include built-in applications 1318 and/or third-party applications 1320. Examples of representative built-in applications 1318 may include, but are not limited to, a home application, a contacts application, a browser application, a book reader application, a location application, a media application, a messaging application, or a game application.

The third-party applications 1320 may include any of the built-in applications 1318, as well as a broad assortment of other applications. In a specific example, the third-party applications 1320 (e.g., an application developed using the Android™ or iOS™ software development kit (SDK) by an entity other than the vendor of the particular platform) may be mobile software running on a mobile operating system such as iOS™, Android™, or other mobile operating systems. In this example, the third-party applications 1320 may invoke the API calls 1324 provided by the mobile operating system such as the operating system 1336 to facilitate functionality described herein.

The applications 1316 may utilize built-in operating system functions (e.g., kernel 1338, services 1340, or drivers 1342), libraries (e.g., system libraries 1330, API libraries 1332, and other libraries 1334), or framework/middleware 422 to create user interfaces to interact with users of the system. Alternatively, or additionally, in some systems, interactions with a user may occur through a presentation layer, such as the presentation layer 1314. In these systems, the application/module “logic” can be separated from the aspects of the application/module that interact with the user.

Some software architectures utilize virtual machines. In the example of FIG. 13, this is illustrated by a virtual machine 1304. The virtual machine 1304 creates a software environment where applications/modules can execute as if they were executing on a hardware machine (e.g., the machine 1400 of FIG. 14). The virtual machine 1304 is hosted by a host operating system (e.g., the operating system 1336) and typically, although not always, has a virtual machine monitor, which manages the operation of the virtual machine 1304 as well as the interface with the host operating system (e.g., the operating system 1336). A software architecture executes within the virtual machine 1304, such as an operating system 1312, libraries 1310, frameworks 1308, applications 1316, or a presentation layer 1306. These layers of software architecture executing within the virtual machine 1304 can be the same as corresponding layers previously described or may be different.

FIG. 14 is a diagrammatic representation of the machine 1400 within which instructions 1408 (e.g., software, a program, an application, an applet, an app, or other executable code) for causing the machine 1400 to perform any one or more of the methodologies discussed herein may be executed. For example, the instructions 1408 may cause the machine 1400 to execute any one or more of the methods described herein. The instructions 1408 transform the general, non-programmed machine 1400 into a particular machine 1400 programmed to carry out the described and illustrated functions in the manner described. The machine 1400 may operate as a standalone device or may be coupled (e.g., networked) to other machines. In a networked deployment, the machine 1400 may operate in the capacity of a server machine or a client machine in a server-client network environment, or as a peer machine in a peer-to-peer (or distributed) network environment. The machine 1400 may comprise, but not be limited to, a server computer, a client computer, a personal computer (PC), a tablet computer, a laptop computer, a netbook, a set-top box (STB), a PDA, an entertainment media system, a cellular telephone, a smart phone, a mobile device, a wearable device (e.g., a smart watch), a smart home device (e.g., a smart appliance), other smart devices, a web appliance, a network router, a network switch, a network bridge, or any machine capable of executing the instructions 1408, sequentially or otherwise, that specify actions to be taken by the machine 1400. Further, while only a single machine 1400 is illustrated, the term “machine” shall also be taken to include a collection of machines that individually or jointly execute the instructions 1408 to perform any one or more of the methodologies discussed herein.

The machine 1400 may include processors 1402, memory 1404, and I/O components 1442, which may be configured to communicate with each other via a bus 1444. In an example, the processors 1402 (e.g., a Central Processing Unit (CPU), a Reduced Instruction Set Computing (RISC) processor, a Complex Instruction Set Computing (CISC) processor, a Graphics Processing Unit (GPU), a Digital Signal Processor (DSP), an ASIC, a Radio-Frequency Integrated Circuit (RFIC), another processor, or any suitable combination thereof) may include, for example, a processor 1406 and a processor 1410 that execute the instructions 1408. The term “processor” is intended to include multi-core processors that may comprise two or more independent processors (sometimes referred to as “cores”) that may execute instructions contemporaneously. Although FIG. 14 shows multiple processors 1402, the machine 1400 may include a single processor with a single core, a single processor with multiple cores (e.g., a multi-core processor), multiple processors with a single core, multiple processors with multiples cores, or any combination thereof.

The memory 1404 includes a main memory 1412, a static memory 1414, and a storage unit 1416, both accessible to the processors 1402 via the bus 1444. The main memory 1404, the static memory 1414, and storage unit 1416 store the instructions 1408 embodying any one or more of the methodologies or functions described herein. The instructions 1408 may also reside, completely or partially, within the main memory 1412, within the static memory 1414, within machine-readable medium 1418 within the storage unit 1416, within at least one of the processors 1402 (e.g., within the processor's cache memory), or any suitable combination thereof, during execution thereof by the machine 1400.

The I/O components 1442 may include a wide variety of components to receive input, provide output, produce output, transmit information, exchange information, capture measurements, and so on. The specific I/O components 1442 that are included in a particular machine will depend on the type of machine. For example, portable machines such as mobile phones may include a touch input device or other such input mechanisms, while a headless server machine will likely not include such a touch input device. It will be appreciated that the I/O components 1442 may include many other components that are not shown in FIG. 14. In various examples, the I/O components 1442 may include output components 1428 and input components 1430. The output components 1428 may include visual components (e.g., a display such as a plasma display panel (PDP), a light emitting diode (LED) display, a liquid crystal display (LCD), a projector, or a cathode ray tube (CRT)), acoustic components (e.g., speakers), haptic components (e.g., a vibratory motor, resistance mechanisms), other signal generators, and so forth. The input components 1430 may include alphanumeric input components (e.g., a keyboard, a touch screen configured to receive alphanumeric input, a photo-optical keyboard, or other alphanumeric input components), point-based input components (e.g., a mouse, a touchpad, a trackball, a joystick, a motion sensor, or another pointing instrument), tactile input components (e.g., a physical button, a touch screen that provides location and/or force of touches or touch gestures, or other tactile input components), audio input components (e.g., a microphone), and the like.

In further examples, the I/O components 1442 may include biometric components 1432, motion components 1434, environmental components 1436, or position components 1438, among a wide array of other components. For example, the biometric components 1432 include components to detect expressions (e.g., hand expressions, facial expressions, vocal expressions, body gestures, or eye tracking), measure biosignals (e.g., blood pressure, heart rate, body temperature, perspiration, or brain waves), identify a person (e.g., voice identification, retinal identification, facial identification, fingerprint identification, or electroencephalogram-based identification), and the like. The motion components 1434 include acceleration sensor components (e.g., accelerometer), gravitation sensor components, rotation sensor components (e.g., gyroscope), and so forth. The environmental components 1436 include, for example, illumination sensor components (e.g., photometer), temperature sensor components (e.g., one or more thermometers that detect ambient temperature), humidity sensor components, pressure sensor components (e.g., barometer), acoustic sensor components (e.g., one or more microphones that detect background noise), proximity sensor components (e.g., infrared sensors that detect nearby objects), gas sensors (e.g., gas detection sensors to detection concentrations of hazardous gases for safety or to measure pollutants in the atmosphere), or other components that may provide indications, measurements, or signals corresponding to a surrounding physical environment. The position components 1438 include location sensor components (e.g., a GPS receiver component), altitude sensor components (e.g., altimeters or barometers that detect air pressure from which altitude may be derived), orientation sensor components (e.g., magnetometers), and the like.

Communication may be implemented using a wide variety of technologies. The I/O components 1442 further include communication components 1440 operable to couple the machine 1400 to a network 1420 or devices 1422 via a coupling 1424 and a coupling 1426, respectively. For example, the communication components 1440 may include a network interface component or another suitable device to interface with the network 1420. In further examples, the communication components 1440 may include wired communication components, wireless communication components, cellular communication components, Near Field Communication (NFC) components, Bluetooth® components (e.g., Bluetooth® Low Energy), Wi-Fi® components, and other communication components to provide communication via other modalities. The devices 1422 may be another machine or any of a wide variety of peripheral devices (e.g., a peripheral device coupled via a USB).

Moreover, the communication components 1440 may detect identifiers or include components operable to detect identifiers. For example, the communication components 1440 may include Radio Frequency Identification (RFID) tag reader components, NFC smart tag detection components, optical reader components (e.g., an optical sensor to detect one-dimensional bar codes such as Universal Product Code (UPC) bar code, multi-dimensional bar codes such as Quick Response (QR) code, Aztec code, Data Matrix, Dataglyph, MaxiCode, PDF417, Ultra Code, UCC RSS-2D bar code, and other optical codes), or acoustic detection components (e.g., microphones to identify tagged audio signals). In addition, a variety of information may be derived via the communication components 1440, such as location via Internet Protocol (IP) geolocation, location via Wi-Fi® signal triangulation, location via detecting an NFC beacon signal that may indicate a particular location, and so forth.

The various memories (e.g., memory 1404, main memory 1412, static memory 1414, and/or memory of the processors 1402) and/or storage unit 1416 may store one or more sets of instructions and data structures (e.g., software) embodying or used by any one or more of the methodologies or functions described herein. These instructions (e.g., the instructions 1408), when executed by processors 1402, cause various operations to implement the disclosed examples.

The instructions 1408 may be transmitted or received over the network 1420, using a transmission medium, via a network interface device (e.g., a network interface component included in the communication components 1440) and using any one of a number of well-known transfer protocols (e.g., hypertext transfer protocol (HTTP)). Similarly, the instructions 1408 may be transmitted or received using a transmission medium via the coupling 1426 (e.g., a peer-to-peer coupling) to the devices 1422.

In view of the disclosure above, various examples are set forth below. It should be noted that one or more features of an example, taken in isolation or combination, should be considered within the disclosure of this application.
Example 1. A system comprising: one or more hardware processors; and at least one machine-storage medium for storing instructions that, when executed by the one or more hardware processors, cause the one or more hardware processors to perform operations comprising: communicating with a flexible pixelated sensor array configured to directly detect skin topology features, the flexible pixelated sensor array including pixels arranged to detect signal differences between skin ridge contact locations and skin valley locations, the flexible pixelated sensor array being shaped into a non-planar configuration having one or more surface portions oriented at different angles relative to each other; and causing the flexible pixelated sensor array to capture biometric features from multiple portions of a user's hand during a single hand placement.
Example 2. The system of Example 1, wherein the captured biometric features include at least one of fingerprints from multiple fingers or a palm print.
Example 3. The system of Example 2, wherein the captured biometric features further include a thumbprint.
Example 4. The system of any one of Examples 1-3, the operations further comprising: causing the flexible pixelated sensor array to capture palm prints and fingerprints during the single hand placement.
Example 5. The system of Example 4, the operations further comprising: causing the flexible pixelated sensor array to capture a thumbprint on a surface portion while capturing fingerprints on an angled surface portion during the single hand placement.
Example 6. The system of any one of Examples 1-5, wherein the non-planar configuration comprises a conical shape having a top surface for thumb placement.
Example 7. The system of Example 6, wherein the operations further comprise: causing the flexible pixelated sensor array to capture rolled fingerprints on the top surface by enabling a user to roll individual fingers across the top surface while maintaining the conical shape for palm and finger placement.
Example 8. The system of any one of Examples 6-7, wherein the conical shape comprises an additional surface for an additional thumb placement, the operations comprising: causing the flexible pixelated sensor array to capture a first thumbprint of a first thumb placed on the top surface, a second thumbprint of a second thumb placed on the additional surface, and a plurality of fingerprints on an angled surface portion during the single hand placement. While the disclosed techniques are described in the context of a “flat” surface, similar techniques are similarly applicable to a surface that is substantially flat and has some amount of curvature.
Example 9. The system of any one of Examples 6-8, wherein the conical shape includes two separate sensitive areas configured to capture biometric features respectively from two hands during the single hand placement, the two separate sensitive areas being separated by a gap to accommodate ergonomic hand placement.
Example 10. The system of Example 9, the separation between the sensitive areas corresponding to approximately a shoulder width.
Example 11. The system of any one of Examples 1-10, wherein the non-planar configuration comprises a cylindrical shape having one or more angled side surfaces for thumb placement.
Example 12. The system of any one of Examples 1-11, wherein the non-planar configuration comprises a pyramidal structure having at least three angled surfaces configured to capture thumb prints from either a left hand or a right hand using respective surfaces of the at least three angled surfaces.
Example 13. The system of Example 12, wherein the operations further comprise: causing the flexible pixelated sensor array to capture fingerprints from two or more fingers on a first surface of the three angled surfaces while capturing a thumb print on one of the remaining two angled surfaces during the single hand placement.
Example 14. The system of any one of Examples 1-13, wherein the flexible pixelated sensor array comprises a thin-film transistor (TFT) array fabricated on an ultrathin glass or plastic substrate.
Example 15. The system of Example 14, wherein the pixels are configured to detect at least one of optical signals, electrical signals, capacitive signals, impedance signals, or ultrasonic signals.
Example 16. The system of any one of Examples 1-15, wherein the non-planar configuration comprises: a curved surface portion configured to conform to a palm of the user's hand; a flat surface portion connected to the curved surface portion and configured to capture fingerprints from multiple fingers; and wherein the flat surface portion is further configured to enable capture of rolled fingerprints by allowing individual fingers to be rolled across edges of the flat surface portion.
Example 17. The system of any one of Examples 1-16, wherein the sensors are supported by a flexible mechanical support that is at least partially compliant to aid in ergonomical matching of the sensor surface to a geometry of the skin topology being presented.
Example 18. A method comprising: communicating with a flexible pixelated sensor array configured to directly detect skin topology features, the flexible pixelated sensor array including pixels arranged to detect signal differences between skin ridge contact locations and skin valley locations, the flexible pixelated sensor array being shaped into a non-planar configuration having one or more surface portions oriented at different angles relative to each other; and causing the flexible pixelated sensor array to capture biometric features from multiple portions of a user's hand during a single hand placement.
Example 19. A method of manufacturing a flexible pixelated sensor array, comprising: fabricating a thin-film transistor (TFT) array on a flexible substrate, the TFT array including pixels configured to detect signal differences between skin ridge contact locations and skin valley locations; patterning the pixels of the TFT array in a regular grid on the flexible substrate during manufacturing; separating the flexible substrate with the patterned TFT array from a temporary support backplane; and shaping the flexible substrate with the patterned TFT array into a non-planar configuration having one or more surface portions oriented at different angles relative to each other, the shaped configuration being supported by a mechanical structure to maintain the non-planar shape while allowing partial compliance to pressure from hand contact.
Example 20. The method of Example 19, wherein shaping the flexible substrate comprises at least one of forming a conical configuration having a flat top surface, forming a cylindrical configuration having angled side surfaces, forming a configuration having a curved portion for palm contact and a flat portion for finger contact, or forming a pyramidal configuration having at least three angled surfaces.

While a flat platen area off of the various curved platen areas is shown and described above, this does not require the flat platen area to be truly flat. In some cases, the flat platen area could be curved either convex or concave for purposes of ergonomics or to facilitate the capture of more of a fingerprint (e.g., for the case of a concave platen area).

Although examples have been described, it will be evident that various modifications and changes may be made to these examples without departing from the broader scope of the present disclosure. Accordingly, the specification and drawings are to be regarded in an illustrative rather than a restrictive sense. The accompanying drawings that form a part hereof, show by way of illustration, and not of limitation, specific examples in which the subject matter may be practiced. The examples illustrated are described in sufficient detail to enable those skilled in the art to practice the teachings disclosed herein. Other examples may be utilized and derived therefrom, such that structural and logical substitutions and changes may be made without departing from the scope of this disclosure. This Detailed Description, therefore, is not to be taken in a limiting sense, and the scope of various examples is defined only by the appended claims, along with the full range of equivalents to which such claims are entitled.

Such examples of the inventive subject matter may be referred to herein, individually and/or collectively, by the term “invention” merely for convenience and without intending to voluntarily limit the scope of this application to any single invention or inventive concept if more than one is in fact disclosed. Thus, although specific examples have been illustrated and described herein, it should be appreciated that any arrangement calculated to achieve the same purpose may be substituted for the specific examples shown. This disclosure is intended to cover any and all adaptations or variations of various examples. Combinations of the above examples, and other examples not specifically described herein, will be apparent to those of skill in the art upon reviewing the above description.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus the following claims are hereby incorporated into the Detailed Description, with each claim standing on its own as a separate example.

What is claimed is:

1. A system comprising:
one or more hardware processors; and
at least one machine-storage medium for storing instructions that, when executed by the one or more hardware processors, cause the one or more hardware processors to perform operations comprising:
communicating with a flexible pixelated sensor array configured to directly detect skin topology features, the flexible pixelated sensor array including pixels arranged to detect signal differences between skin ridge contact locations and skin valley locations, the flexible pixelated sensor array being shaped into a non-planar configuration having one or more surface portions oriented at different angles relative to each other; and
causing the flexible pixelated sensor array to capture biometric features from multiple portions of a user's hand during a single hand placement.

2. The system of claim 1, wherein the captured biometric features include at least one of fingerprints from multiple fingers or a palm print.

3. The system of claim 2, wherein the captured biometric features further include a thumbprint.

4. The system of claim 1, the operations further comprising:
causing the flexible pixelated sensor array to capture palm prints and fingerprints during the single hand placement.

5. The system of claim 4, the operations further comprising:
causing the flexible pixelated sensor array to capture a thumbprint on a surface portion while capturing fingerprints on an angled surface portion during the single hand placement.

6. The system of claim 1, wherein the non-planar configuration comprises a conical shape having a top surface for thumb placement.

7. The system of claim 6, wherein the operations further comprise:
causing the flexible pixelated sensor array to capture rolled fingerprints on the top surface by enabling a user to roll individual fingers across the top surface while maintaining the conical shape for palm and finger placement.

8. The system of claim 6, wherein the conical shape comprises an additional surface for an additional thumb placement, the operations comprising:
causing the flexible pixelated sensor array to capture a first thumbprint of a first thumb placed on the top surface, a second thumbprint of a second thumb placed on the additional surface, and a plurality of fingerprints on an angled surface portion during the single hand placement.

9. The system of claim 6, wherein the conical shape includes two separate sensitive areas configured to capture biometric features respectively from two hands during the single hand placement, the two separate sensitive areas being separated by a gap to accommodate ergonomic hand placement.

10. The system of claim 9, the separation between the sensitive areas corresponding to approximately a shoulder width.

11. The system of claim 1, wherein the non-planar configuration comprises a cylindrical shape having one or more angled side surfaces for thumb placement.

12. The system of claim 1, wherein the non-planar configuration comprises a pyramidal structure having at least three angled surfaces configured to capture thumb prints from either a left hand or a right hand using respective surfaces of the at least three angled surfaces.

13. The system of claim 12, wherein the operations further comprise:
causing the flexible pixelated sensor array to capture fingerprints from two or more fingers on a first surface of the three angled surfaces while capturing a thumb print on one of the remaining two angled surfaces during the single hand placement.

14. The system of claim 1, wherein the flexible pixelated sensor array comprises a thin-film transistor (TFT) array fabricated on an ultrathin glass or plastic substrate.

15. The system of claim 14, wherein the pixels are configured to detect at least one of optical signals, electrical signals, capacitive signals, impedance signals, or ultrasonic signals.

16. The system of claim 1, wherein the non-planar configuration comprises:
a curved surface portion configured to conform to a palm of the user's hand;
a flat surface portion connected to the curved surface portion and configured to capture fingerprints from multiple fingers; and
wherein the flat surface portion is further configured to enable capture of rolled fingerprints by allowing individual fingers to be rolled across edges of the flat surface portion.

17. The system of claim 1, wherein the sensors are supported by a flexible mechanical support that is at least partially compliant to aid in ergonomical matching of the sensor surface to a geometry of the skin topology being presented.

18. A method comprising:
communicating with a flexible pixelated sensor array configured to directly detect skin topology features, the flexible pixelated sensor array including pixels arranged to detect signal differences between skin ridge contact locations and skin valley locations, the flexible pixelated sensor array being shaped into a non-planar configuration having one or more surface portions oriented at different angles relative to each other; and
causing the flexible pixelated sensor array to capture biometric features from multiple portions of a user's hand during a single hand placement.

19. A method of manufacturing a flexible pixelated sensor array, comprising:
fabricating a thin-film transistor (TFT) array on a flexible substrate, the TFT array including pixels configured to detect signal differences between skin ridge contact locations and skin valley locations;
patterning the pixels of the TFT array in a regular grid on the flexible substrate during manufacturing;
separating the flexible substrate with the patterned TFT array from a temporary support backplane; and
shaping the flexible substrate with the patterned TFT array into a non-planar configuration having one or more surface portions oriented at different angles relative to each other, the shaped configuration being supported by a mechanical structure to maintain the non-planar shape while allowing partial compliance to pressure from hand contact.

20. The method of claim 19, wherein shaping the flexible substrate comprises at least one of forming a conical configuration having a flat top surface, forming a cylindrical configuration having angled side surfaces, forming a configuration having a curved portion for palm contact and a flat portion for finger contact, or forming a pyramidal configuration having at least three angled surfaces.
